(19) United States
(12) Patent Application Publication
(10) Pub. No.: US 2009/0231921 A1
(43) Pub. Date: Sep. 17, 2009

(54) MANUFACTURING METHOD OF NONVOLATILE SEMICONDUCTOR STORAGE DEVICE AND NONVOLATILE SEMICONDUCTOR STORAGE DEVICE

(75) Inventors: Shinichiro Kimura, Kunitachi (JP); Yasuhiro Shimamoto, Tokorozawa (JP); Digh Hisamoto, Kokubunji (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/389,361

(22) Filed: Feb. 19, 2009

(30) Foreign Application Priority Data
Mar. 14, 2008 (JP) JP 2008-065097

(51) Int. Cl. G11C 16/06; H01L 21/336; H01L 29/792; G11C 5/14

(52) U.S. Cl. 365/185.18; 438/261; 438/287; 257/324; 365/226; 257/E21.409; 257/E29.309

(57) ABSTRACT

In a nonvolatile semiconductor storage device having a split-gate memory cell including a control gate electrode and a sidewall memory gate electrode and a single-gate memory cell including a single memory gate electrode on the same silicon substrate, the control gate electrode is formed in a first region via a control gate insulating film, the sidewall memory gate electrode is formed in the first region via a charge trapping film, and at the same time, a single memory gate electrode is formed in a second region via the charge trapping film. At this time, the sidewall memory gate electrode and the single memory gate electrode are formed in the same process, and the control gate electrode and the sidewall memory gate electrode are formed so as to be adjacently disposed to each other in a state of being electrically isolated from each other.

### CROSS-REFERENCE TO RELATED APPLICATION

The present application claims priority from Japanese Patent Application No. JP 2008-065097 filed on Mar. 14, 2008, the content of which is hereby incorporated by reference into this application.

### TECHNICAL FIELD OF THE INVENTION

The present invention relates to a nonvolatile semiconductor storage device, and more particularly to a technique effectively applied to a manufacturing method of a nonvolatile semiconductor storage device embedded in an integrated circuit and the nonvolatile semiconductor storage device.

### BACKGROUND OF THE INVENTION

With the development of an advanced information society, demands for the improvement in performance and the improvement in productivity have been increasing in a semiconductor device composed of an integrated circuit for logical operation (logic circuit or simply logic), a nonvolatile semiconductor storage element (nonvolatile memory, flash memory, or simply memory) and others, in which functional circuits are configured by integrating a plurality of semiconductor elements formed on a semiconductor substrate.

In particular, the microcomputers to be mounted on various products are required to have a nonvolatile memory for storing a program for causing a logic circuit to perform arithmetic operation, data necessary for operation and others.

Also, in the development stage of products, development of software simultaneous with the determination of the specification of the products is desired in order to shorten the development period thereof. For this reason, software changes every time the specification is changed, and it is necessary to rewrite a part of a program when a software defect (bug or error) is deleted.

In order to meet the demands above, development and practical application of a so-called System on Chip (SoC) in which a logic circuit, a rewritable nonvolatile memory and others are embedded on the same semiconductor substrate are now in progress.

As a nonvolatile memory element to be embedded together with a logic circuit on a semiconductor substrate, a so-called MONOS nonvolatile memory element is known, in which an insulating film (Insulator) of a MIS (Metal Insulator Semiconductor) field effect transistor is replaced with a stacked film of silicon oxide film (Oxide)/silicon nitride film (Nitride)/silicon oxide film (Oxide).

For example, with respect to the microcomputer having a nonvolatile memory incorporated therein, Japanese Patent Application Laid-Open Publication No. 2006-66009 (patent document 1) discloses the technique for properly using nonvolatile memories for both the program storage and the data storage.

Also, for example, Japanese Patent Application Laid-Open Publication No. 2007-194511 (patent document 2) discloses a technique for improving the write and erase endurance by replacing a silicon nitride film with a film whose silicon content is higher than that of stoichiometric composition in a MONOS nonvolatile memory element.

### SUMMERY OF THE INVENTION

As described above, there are at least two types of applications of nonvolatile memories embedded in a microcomputer, that is, program storage and data storage. According to the studies by the present inventors, the characteristics required for nonvolatile memories differ depending on these applications. More specifically, a nonvolatile memory for program storage requires high-speed operation (high-speed performance), and a nonvolatile memory for data storage requires high endurance to write and erase cycles (high write and erase endurance).

The techniques disclosed in patent document 1 studied by the present inventors will be described as a method for properly using the nonvolatile memories for respective applications. FIG. 28 shows an explanatory drawing of a microcomputer Ax studied by the present inventors.

The microcomputer Ax studied by the present inventors includes a central processing unit (CPU) Bx, a random access memory (RAM) Cx, and a nonvolatile memory region for program storage (hereinafter simply referred to as program memory region) FLpx. The random access memory Cx is a nonvolatile memory to be a work region of the central processing unit Bx. Since high-speed data processing is required between the above elements, they are connected to a bus state controller (BSC) Ex via a high-speed bus DX that is a path with small wiring resistance.

Also, the microcomputer Ax studied by the present inventors further includes a timer (TMR) Fx, an analog/digital (A/D) converter Gx, an input/output (I/O) port Hx, and a serial interface controller (SCI) Ix. Since high-speed operation is not so much required between these elements, they are connected to a low-speed bus Jx different from the high-speed bus Dx. Then, a nonvolatile memory region for data storage (hereinafter simply referred to as data memory region) FLdx is connected to the bus controller Ex via the low-speed bus Jx.

As described above, data communication paths to be brought into conduction with the region where high-speed operation is required and the region where high-speed operation is not so much required are separately provided by the high-speed bus Dx and the low-speed bus Jx, respectively. The program memory region FLpx is connected to the former and the data memory region FLdx is connected to the latter, and they are controlled separately. By this means, speed-up of the program memory region FLpx can be achieved without deteriorating the write and erase endurance of the data memory region FLdx. The reason thereof will be described below.

The high-speed performance of a nonvolatile memory means that more current can be supplied to a memory cell (minimum unit) in the reading. For its achievement, it is necessary to lower the threshold voltage of the predetermined memory cell in one way or another. For example, in the memory cells studied by the present inventors, a carrier (charge) is injected into a charge trapping insulating film under a floating gate electrode or a gate electrode, thereby storing electric charge. By this means, a threshold voltage of a field-effect transistor is lowered, and a current value when read voltage is applied is increased.

The reduction of a threshold voltage of a memory cell mentioned here is equivalent to applying electric stress to the memory cell, and it causes the degradation of write and erase endurance. Thus, from the standpoint of changing the threshold voltage of a nonvolatile memory, the speed-up and the higher endurance are in a trade-off relation.

For its solution, in the technique of the above-described patent document 1, focusing attention on that the nonvolatile memory for data storage that requires high write and erase endurance does not require high-speed performance so much, the threshold voltage of a memory cell is not lowered. By this means, the stress to be applied to a memory cell is reduced, and the speed-up of the memory for program can be achieved without deteriorating the write and erase endurance of a memory for data.

Meanwhile, according to the further studies made by the present inventors, in the situation where further performance improvement of a nonvolatile semiconductor storage device is desired, the improvement of the write and erase endurance of the memory for data is also required in addition to the further speed-up of the memory for program. However, it is known that, when a nonvolatile memory that can achieve higher endurance is applied, the speed-up is hindered due to the trade-off relation shown above. More specifically, the further studies made by the present inventors have revealed that the high-speed nonvolatile memories can be separately used from the applications where the write and erase endurance is not required by the above-described technique, but it is difficult to form a nonvolatile memory that can achieve the high-speed operation and a nonvolatile memory that can achieve the high endurance on the same substrate. As a result, it is difficult to improve the performance of the nonvolatile semiconductor storage device.

Therefore, an object of the present invention is to provide a technique capable of improving the performance of a nonvolatile semiconductor storage device.

The above and other objects and novel characteristics of the present invention will be apparent from the description of this specification and the accompanying drawings.

A plurality of inventions will be disclosed in this application, and one of the embodiments thereof will be briefly described as follows.

That is, a manufacturing method of a nonvolatile semiconductor storage device including a first storage element having a first gate electrode and a second gate electrode and a second storage element having a third gate electrode on the same semiconductor substrate is provided, and the method comprises the steps of: forming a first gate electrode in a first region on a main surface of a semiconductor substrate via a first gate insulating film; and forming a second gate electrode in the first region on the main surface of the semiconductor substrate via a charge trapping insulating film and at the same time forming a third gate electrode in a second region via a charge trapping insulating film. At this time, the second gate electrode and the third gate electrode are formed in the same process, and the first gate electrode and the second gate electrode are adjacently disposed to each other in a state of being electrically isolated from each other.

The effects obtained by typical one of the inventions disclosed in this application will be briefly described below.

That is, it is possible to improve the performance of a nonvolatile semiconductor storage device.

### BRIEF DESCRIPTIONS OF THE DRAWINGS

FIG. 1 is a cross sectional view of a principal part of a nonvolatile semiconductor storage device according to the first embodiment of the present invention;

FIG. 2 is a cross sectional view of a principal part in a manufacturing process of a nonvolatile semiconductor storage device according to the first embodiment of the present invention;

FIG. 3 is a cross sectional view of a principal part in a manufacturing process of a nonvolatile semiconductor storage device continued from FIG. 2;

FIG. 4 is a cross sectional view of a principal part in a manufacturing process of a nonvolatile semiconductor storage device continued from FIG. 3;

FIG. 5 is a cross sectional view of a principal part in a manufacturing process of a nonvolatile semiconductor storage device continued from FIG. 4;

FIG. 6 is a cross sectional view of a principal part in a manufacturing process of a nonvolatile semiconductor storage device continued from FIG. 5;

FIG. 7 is a cross sectional view of a principal part in a manufacturing process of a nonvolatile semiconductor storage device continued from FIG. 6;

FIG. 8 is a cross sectional view of another principal part in the same manufacturing process as FIG. 7 in a manufacturing process of a nonvolatile semiconductor storage device according to the first embodiment of the present invention;

FIG. 9 is a cross sectional view of a principal part in a manufacturing process of a nonvolatile semiconductor storage device continued from FIG. 7;

FIG. 10 is a cross sectional view of a principal part in a manufacturing process of a nonvolatile semiconductor storage device continued from FIG. 9;

FIG. 11 is a cross sectional view of a principal part in a manufacturing process of a nonvolatile semiconductor storage device continued from FIG. 10;

FIG. 12 is a cross sectional view of a principal part in a manufacturing process of a nonvolatile semiconductor storage device continued from FIG. 11;

FIG. 13 is a cross sectional view of a principal part in a manufacturing process of a nonvolatile semiconductor storage device continued from FIG. 12;

FIG. 14 is a cross sectional view of a principal part in a manufacturing process of a nonvolatile semiconductor storage device continued from FIG. 13;

FIG. 15 is a cross sectional view of a principal part in a manufacturing process of a nonvolatile semiconductor storage device continued from FIG. 6;

FIG. 16 is a cross sectional view of a principal part in a manufacturing process of a nonvolatile semiconductor storage device continued from FIG. 15;

FIG. 17 is a cross sectional view of a principal part in a manufacturing process of a nonvolatile semiconductor storage device continued from FIG. 16;

FIG. 18 is a cross sectional view of a principal part of a nonvolatile semiconductor storage device according to the second embodiment of the present invention;

FIG. 19 is a cross sectional view of a principal part in a manufacturing process of a nonvolatile semiconductor storage device according to the second embodiment of the present invention continued from FIG. 4;

FIG. 20 is a cross sectional view of a principal part in a manufacturing process of a nonvolatile semiconductor storage device continued from FIG. 19;

FIG. 21 is a cross sectional view of a principal part in a manufacturing process of a nonvolatile semiconductor storage device continued from FIG. 20;

FIG. 22 is a cross sectional view of a principal part in a manufacturing process of a nonvolatile semiconductor storage device continued from FIG. 21;

FIG. 23 is a cross sectional view of a principal part in a manufacturing process of a nonvolatile semiconductor storage device continued from FIG. 22;

FIG. 24 is an explanatory drawing of a nonvolatile semiconductor storage device according to the third embodiment of the present invention;

FIG. 25 is a circuit diagram of a nonvolatile semiconductor storage device according to the third embodiment of the present invention;

FIG. 26 is another circuit diagram of a nonvolatile semiconductor storage device according to the third embodiment of the present invention;

FIG. 27 is another circuit diagram of a nonvolatile semiconductor storage device according to the third embodiment of the present invention;

FIG. 28 is an explanatory drawing of a nonvolatile semiconductor storage device studied by the present inventors;

FIG. 29 is a cross sectional view of a principal part of a nonvolatile semiconductor storage device studied by the present inventors;

FIG. 30 is an explanatory drawing showing an operation of a nonvolatile semiconductor storage device studied by the present inventors;

FIG. 31 is an explanatory drawing showing another operation of a nonvolatile semiconductor storage device studied by the present inventors;

FIG. 32 is a cross sectional view of a principal part of another nonvolatile semiconductor storage device studied by the present inventors;

FIG. 33 is a cross sectional view of a principal part of another nonvolatile semiconductor storage device studied by the present inventors;

FIG. 34 is an explanatory drawing showing an operation of another nonvolatile semiconductor storage device studied by the present inventors; and

FIG. 35 is an explanatory drawing showing another operation of another nonvolatile semiconductor storage device studied by the present inventors.

### DESCRIPTION OF THE PREFERRED EMBODIMENTS

Components having the same function are denoted by the same reference numbers throughout the drawings for describing the embodiments, and the repetitive description thereof will be omitted as far as possible. Hereinafter, embodiments of the present invention will be described in detail with reference to the accompanying drawings.

### First Embodiment

In the first embodiment, the configuration of a nonvolatile memory and a problem seen in the memory operation thereof studied by the present inventors will be first described in detail.

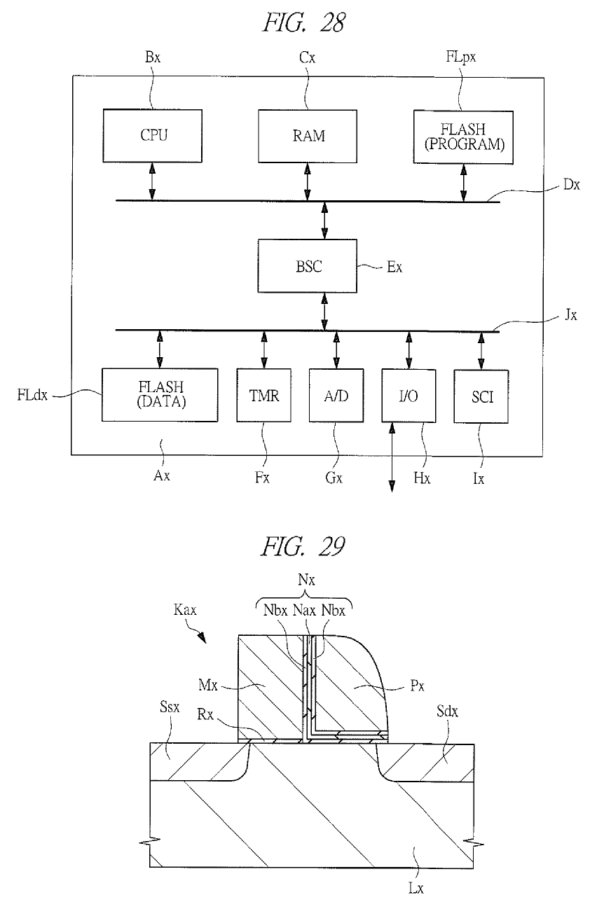

A split-gate memory cell is known as one candidate of a nonvolatile memory that can operate at high speed. FIG. 29 shows a cross sectional view of a principal part of a split-gate memory cell Kax having the structure studied by the present inventors. This split-gate memory cell Kax is formed on a semiconductor substrate Lx. A charge trapping film Nx is formed on a sidewall of a control gate electrode Mx formed on a main surface of the semiconductor substrate Lx, and further, a sidewall memory gate electrode Px is formed as a sidewall film of the control gate electrode Mx. A control gate insulating film Rx is formed between the control gate electrode Mx and the semiconductor substrate Lx. Also, the charge trapping film Nx is formed between the sidewall memory gate electrode Px and the semiconductor substrate Lx. More specifically, the charge trapping film Nx is formed in an integrated manner from the sidewall of the control gate electrode Mx to directly below the sidewall memory gate electrode Px. The charge trapping film Nx has a three-layer structure in which one layer of a silicon nitride film NaX is sandwiched between two layers of silicon oxide films Nbx.

A source region Ssx that is a diffusion layer of a conductivity type opposite to that of the semiconductor substrate Lx is formed in the main surface of the semiconductor substrate Lx located laterally below the control gate electrode Mx. Also, a drain region Sdx that is a diffusion layer of a conductivity type opposite to that of the semiconductor substrate Lx is formed in the main surface of the semiconductor substrate Lx located laterally below the sidewall memory gate electrode Px.

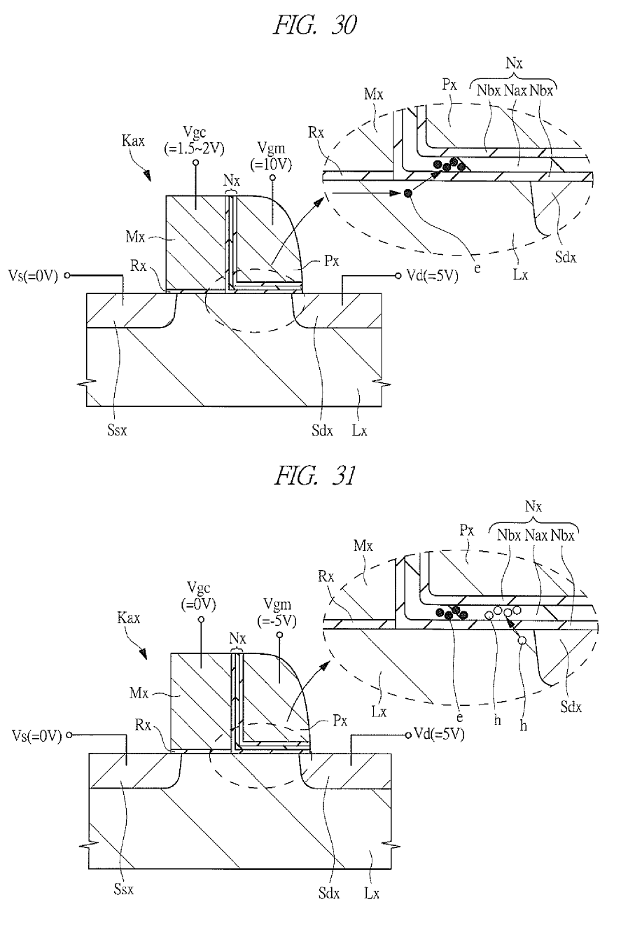

As shown in FIG. 30, a source voltage Vs to be applied to the source region Ssx is set to, for example, 0 V, a positive voltage of approximately 5 V is applied to the drain region Sdx as a drain voltage Vd, and a voltage of approximately 10 V is applied to the sidewall memory gate electrode Px as a memory gate voltage Vgm. In addition, a voltage of, for example, approximately 1.5 to 2 V is applied to the control gate electrode Mx as a control gate voltage Vgc to turn-on a MIS transistor of the control gate to supply the current. By this means, an electron e flowing just under the control gate electrode Mx is accelerated in the high electric field region generated by the drain voltage Vd and also accelerated in the longitudinal electric field by the memory gate voltage Vgm, and the accelerated electron e is then injected into the charge trapping film Nx in a high energy state and captured. The electrons e are accumulated by this mechanism, and when the semiconductor substrate Lx is of p type, the threshold voltage of the MIS semiconductor generated by the sidewall memory gate electrode Px increases. Therefore, the memory gate is in an off state even when the control gate is in an on state, and a state where current does not flow can be achieved as a whole. This state is a write state, and it is equivalent to 0 in a logic level.

Since this write operation is caused by a slight current controlled by the control gate electrode Mx, it has a characteristic that current flowing at the time of writing is low. Furthermore, the write speed is fast and the time required to write one bit is several microseconds.

Meanwhile, as shown in FIG. 31, in an erase operation, the source voltage Vs is set to 0 V, a positive voltage of approximately 5 V is applied as the drain voltage Vd, and a negative voltage of approximately −5 V is applied as the memory gate voltage Vgm. The control gate voltage Vgc is set to, for example, 0 V so that the MIS semiconductor of the control gate is brought into an off state. In such voltage conditions, a band-to-band tunneling occurs between the drain region Sdx and the semiconductor substrate Lx, and a number of electrons e and holes h are generated. The generated electrons e are attracted by the positive voltage applied to the drain region Sdx and flows into the drain region Sdx. The holes h flow toward the semiconductor substrate Lx in a ground state, but some of the holes are moved to the control gate electrode Mx side by the positive voltage applied to the drain region Sdx. At this time, the holes h are attracted by the negative voltage applied to the sidewall memory gate electrode Px and injected into the charge trapping film Nx under the sidewall memory gate electrode Px.

Since the electrons e are already accumulated in this charge trapping film Nx in the write state, the electrons e disappear when the holes h are injected, and surplus holes h remain. As a result, when the semiconductor substrate Lx is of p type, the threshold voltage of the MIS semiconductor generated by the sidewall memory gate electrode Px lowers, and the state where current flows when the control gate is turned on can be achieved. This state is an erase state and it is equivalent to 1 in a logic level.

This erase mechanism using the band-to-band tunneling has a characteristic that the threshold voltage can be significantly lowered and high-speed and deep erase is possible.

The above-described nonvolatile memory using the split-gate memory cell Kax has a characteristic other than that the write/erase operation can be performed at high speed. As described in the description of the erase operation, the threshold voltage can be significantly lowered by controlling the number of holes h to be injected. The reduction of the threshold voltage means that current flowing to a memory cell at the time of the read operation increases, and it is equivalent to the increase in operation speed. In addition, low-power operation is possible because a large current can be obtained without increasing the voltage to be applied to the memory gate so much.

However, the further studies made by the present inventors have found that the following problem exists in the split-gate memory cell Kax. It is caused due to the difference between the position where electrons e are injected in the write operation and the position where holes h are injected in the erase operation.

As described with reference to FIG. 30, the electron e flowing just under the control gate electrode Mx is accelerated by the high field region existing near the boundary between the control gate electrode Mx and the sidewall memory gate Px in the write operation. Then, the accelerated electron e is injected into the charge trapping film Nx with maintaining its high energy state. At this time, the distribution of the injection positions of the electron e is biased to a region close to the control gate electrode Mx in the charge trapping film Nx.

Meanwhile, as described with reference to FIG. 31, injection of the hole h generated by the band-to-band tunneling into the charge trapping film Nx is used in the erase operation. At this time, with respect to the injection of the hole h into the charge trapping film Nx, the movement in a lateral direction of the semiconductor substrate Lx due to an electric field occurs, and the distribution of the injection positions thereof is biased to the neighborhood of the interface between the drain region Sdx and the semiconductor substrate Lx.

As described above, the injection position of the electron e differs from the injection position of the hole h. In addition, in a memory cell using the charge trapping film Nx, the injected charge basically remains at that position in general. Accordingly, the difference in the injection positions as described above causes a mismatch of the charge distribution in the charge trapping film Nx. This mismatch means that one of electric charges thereof remains, and it indicates that the remaining charge is accumulated as the number of times of rewriting increases. And it has been found that the remaining charge causes the decrease in the number of times of rewriting and the deterioration in write and erase characteristics.

The deterioration in characteristic resulting from the above-described mismatch depends on how many electrons e and holes h are injected. More specifically, when the memory cell performance is to be improved by widening the operation ranges of the write state and erase state, a large number of electrons e and holes h need to be injected. As a result, with the increase in the number of times of rewriting, the mismatch becomes obvious, and the number of times of rewriting is restricted. On the other hand, when the wide operation range is not required, the number of electrons e and holes h to be injected can be reduced. In other words, stress is reduced so much. As a result, the number of times of rewriting can be increased. According to the studies made by the present inventors, the number of times of rewriting in the high-performance applications is about several thousand times, and the number of times of rewriting in the applications where high-speed operation is not required is about tens of thousands times.

However, according to the further studies made by the present inventors, the number of times of rewriting of exceeding a half million times and a million times is required in the data memory region FLdx where high write and erase endurance is required as described with reference to FIG. 28. More specifically, it has been found that it is difficult to apply the split-gate memory cell Kax whose number of times of rewriting is tens of thousands times to the data memory region FLdx in the situation where further performance improvement of a nonvolatile semiconductor storage device is desired. Furthermore, the studies by the present inventors have revealed that it is difficult to achieve data rewriting over a million times when the potential of the split-gate memory cell Kax itself is taken into consideration.

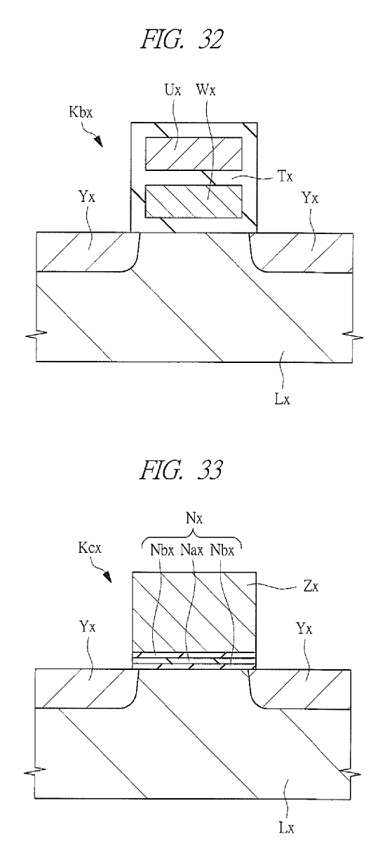

For the solution of the problem above, it is necessary to use not only the split-gate memory cell Kax studied by the present inventors but also a memory cell structure capable of increasing the number of times of rewriting. The floating-gate memory cell Kbx shown in FIG. 32 is known as the memory cell structure having high write and erase endurance. The basic components of the floating-gate memory cell Kbx are the same as those of the MIS transistor. More specifically, a floating gate electrode Wx formed via a gate insulating film Vx and a control gate electrode Ux formed via an interlayer dielectric film Tx are provided as gate electrodes on the semiconductor substrate Lx, and source/drain regions Yx formed in the semiconductor substrate Lx located laterally below the gate electrodes are provided.

Here, the floating gate electrode Wx is formed between the control gate electrode Ux and the semiconductor substrate Lx. The floating gate electrode Wx is covered with, for example, the interlayer dielectric film Tx in an integrated manner and is not electrically connected to any electrode. In other words, it is in a so-called floating state.

Write and erase of the information are carried out by applying voltage to the control gate electrode Ux. When a positive voltage of approximately 20 V is applied to the control gate electrode Ux, an inversion layer of an electron is formed in the neighborhood of the interface with the gate insulating film Vx in the semiconductor substrate Lx. Then, this electron tunnels through the gate insulating film Vx by the high electric field and is injected into the floating gate electrode Wx. The electron injected into the floating gate electrode Wx that is in a floating state cannot get out of it and captured therein. As a result, the threshold voltage of the MIS transistor using the floating gate electrode Wx and the control gate electrode Ux as the gate electrode increases, and the 0 state in a logic level is realized.

Meanwhile, with respect to erase, a negative voltage of approximately −20 V is applied to the control gate electrode Ux. At this time, the holes in the semiconductor substrate Lx are gathered in the neighborhood of the interface with the gate insulating film Vx in the semiconductor substrate Lx. Then, these holes tunnel through the gate insulating film Vx by the high electric field and are injected into the floating gate electrode Wx. The holes injected into the floating gate electrode Wx that is in a floating state cannot get out of it and captured therein.

Since electrons are already accumulated in this floating gate electrode Wx in the write state, the electrons disappear when the holes are injected, and surplus holes remain. As a result, the threshold voltage of the MIS transistor using the floating gate electrode Wx and the control gate electrode Ux as the gate electrode lowers, and the 1 state in a logic level is realized.

The case where high voltages of +20 V and −20 V are applied to the control gate electrode Ux has been described above. Meanwhile, it is also possible to reduce the absolute value of voltage to be applied to the control gate electrode Ux by applying voltage also to the semiconductor substrate Lx. For example, by applying 10 V to the control gate electrode Ux and −10 V to the semiconductor substrate Lx in the write operation, the state relatively equivalent to that obtained by applying 20 V to the control gate electrode Ux can be achieved.

The mechanism of charge injection realized by the voltage application described above is referred to as FN (Fowler-Nordheim) tunnel phenomenon, and since the energy of electrons and holes to be injected is low, damage to the gate insulating film Vx is suppressed. As a result, the number of times of rewriting can be increased.

The present inventors have studied the application of the memory cell using a charge trapping film to a memory cell having the above-described operation mechanism by the FN tunnel phenomenon. More specifically, as a region to accumulate the charges for memory operation, the charge trapping film Nx like in the split-gate memory cell Kax described with reference to FIG. 29 to FIG. 32 is used instead of the floating gate electrode Wx like in the floating-gate memory cell Kbx described with reference to FIG. 32.

FIG. 33 shows a cross sectional view of a principal part of a single-gate memory cell Kcx having the structure studied by the present inventors. The single-gate memory cell Kcx has the source/drain regions Yx formed in the semiconductor substrate Lx similar to that of the floating-gate memory cell Kbx shown in FIG. 32, and the gate electrode structure thereof differs as described below. More specifically, the single-gate memory cell Kcx has a single memory gate electrode Zx formed on the semiconductor substrate Lx via the charge trapping film Nx as its gate electrode.

Here, similar to the charge trapping film Nx in the split-gate memory cell Kax described with reference to FIG. 29, the charge trapping film Nx has a three-layer structure in which one layer of the silicon nitride film NaX is sandwiched between two layers of the silicon oxide films Nbx. In the structures studied by the present inventors, the thickness of the silicon oxide film Nbx of the first layer formed on the main surface of the semiconductor substrate Lx is about 4 nm, the thickness of the silicon nitride film Nax of the second layer is about 8 nm, and the thickness of the silicon oxide film Nbx of the third layer formed on the silicon nitride film Nax is about 6 nm.

As described above, this single-gate memory cell Kcx uses the FN tunnel phenomenon for write operation and erase operations in order to increase the number of times of rewriting.

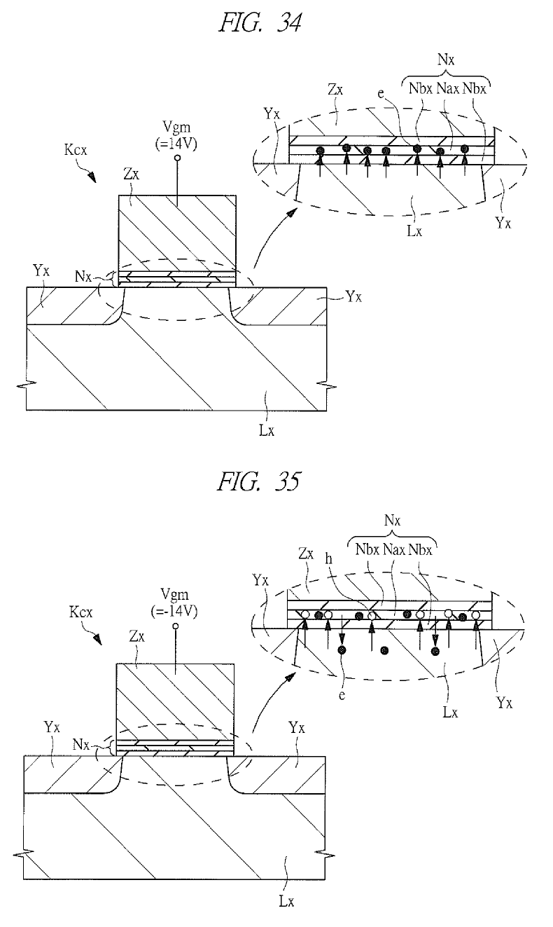

As shown in FIG. 34, a positive voltage of approximately 14 V is applied as the memory gate voltage Vgm to be applied to the single memory gate electrode Zx in the write operation. By this means, the electron e of the inversion layer induced in the neighborhood of the interface with the charge trapping film Nx in the semiconductor substrate Lx is injected into the charge trapping film Nx. The injected electron e is mainly captured at the interface between the silicon nitride film Nax and the silicon oxide film Nbx in the charge trapping film Nx. As a result, the threshold voltage in the MIS structures of the single memory gate electrode Zx, the charge trapping film Nx, and the semiconductor substrate Lx increases. Accordingly, even if a read voltage is applied to the single memory gate electrode Zx and a voltage bias is applied between two source/drain regions Yx, current does not flow, and the 0 state in a logic level can be realized.

The reason why applied voltage is low in the single-gate memory cell Kcx compared with the floating-gate memory cell Kbx described with reference to FIG. 32 is that the film thickness of the silicon oxide film Nbx of the charge trapping films Nx disposed between the silicon nitride film Nax and the semiconductor substrate Lx is as small as 4 nm. In the floating-gate memory cell Kbx, the thickness of the insulating film that surrounds the floating gate electrode Wx together with the interlayer dielectric film Tx in an integrated manner is 9 nm so as to prevent the external leakage of the electron captured in the floating gate electrode Wx. Therefore, in order to inject the electron into the floating gate electrode Wx by the FN tunnel phenomenon, approximately 20 V has to be applied to the control gate electrode Ux. Contrary to this, in the single-gate memory cell Kcx using the charge trapping film Nx, write voltage can be reduced as described above, and many advantages can be obtained from the standpoint of memory area reduction and reliability improvement.

Meanwhile, also the erase operation is almost the same as the operation of the floating-gate memory cell Kbx except the value of the applied voltage. More specifically, as shown in FIG. 35, a negative voltage of approximately −14 V is applied as the memory gate voltage Vgm to the single memory gate electrode Zx. By this means, the electrons e accumulated in the charge trapping film Nx are pushed out to the semiconductor substrate Lx or the holes h are injected into the charge trapping film Nx from the semiconductor substrate Lx. As a result, the threshold voltage in the MIS structure lowers, and when read voltage is applied to the single memory gate electrode Zx, current flows between the two biased source/drain regions Yx, thereby realizing the 1 state in a logic level.

Note that, when read voltage is not applied to the single memory gate electrode Zx in the erase state of the single-gate memory cell Kcx as described above, current must not flow. This is an essential condition when nonvolatile memories composed of a single MIS transistor like the single-gate memory cell Kcx are disposed in matrix. This is because accurate reading is not assured if current flows to the memory in the state where read voltage is not applied. For this reason, determination (verify) operation is performed so as to prevent the excessive reduction of the threshold voltage, that is, over-erase state in the erase operation. Of course, the verify operation is necessary also in the write operation.

In the single-gate memory cell Kcx using the FN tunnel phenomenon as described above, damage on the memory is small because high-energy electrons and holes are not required in the write and erase operations. As a result, the number of times of rewriting can be increased. According to the verification made by the present inventors, the number of times of rewriting exceeding a million times is already demonstrated. In other words, the single-gate memory cell Kcx has high write and erase endurance and is suitable for a nonvolatile memory for data storage where the frequent rewriting is required.

Meanwhile, according to the further studies made by the present inventors, this single-gate memory cell Kcx has a problem in high-speed performance in the read operation. The single-gate memory cell Kcx is provided with a three-layer insulating film composed of one layer of a silicon nitride film Nxa and two layers of silicon oxide films Nbx as the charge trapping film Nx under the single memory gate electrode Zx. This three-layer charge trapping film Nx plays a role of a gate insulating film of a MIS transistor.

The thicknesses of the respective films of the charge trapping film Nx are as described above. The equivalent oxide thickness (EOT) thereof is about 14 nm. It can be understood that the gate insulating film (charge trapping film Nx) of the single-gate memory cell Kcx is very thick compared with the typical MIS transistor for logic circuits studied by the present inventors in which the gate insulating film is about 2 nm. More specifically, the further studies made by the present inventors have revealed that, as compared with the MIS transistors used for logic circuits and SRAM (Static Random Access Memory), the single-gate transistor Kcx has a far thicker gate insulating film and is inferior in current drivability when viewed as a MIS transistor.

For this reason, it can be understood that it is difficult to use the single-gate memory cell Kcx for the program memory region FLpx required to perform the high-speed data communication with the central processing unit Bx shown in FIG. 28.

As described above, the further studies made by the present inventors have revealed that the split-gate memory cell Kax shown in FIG. 29 has high-speed performance but the write and erase endurance thereof is low, and the single-gate memory cell Kcx shown in FIG. 33 has high write and erase endurance but the operating speed thereof is low. Then, through the studies made by the investors described above, they have reached the idea to apply the split-gate memory cell Kax with high-speed performance to the program memory region FLpx and apply the single-gate memory cell Kcx with high write and erase endurance to the data memory region FLdx.

However, SoC requires embedding the above memories on the same substrate. In general, embedding devices with different structures and operation mechanisms on the same substrate often leads to the structural mismatching and the disadvantage on the manufacturing process. As a result, it causes decrease in reliability of the completed nonvolatile semiconductor storage device and also reduction in productivity such as the decrease in manufacturing yield and the cost increase resulting from the increase in the number of process steps. Therefore, in the first embodiment, a structure in which the above-described two types of the nonvolatile memory cells are formed on the same substrate and the manufacturing process thereof will be shown below.

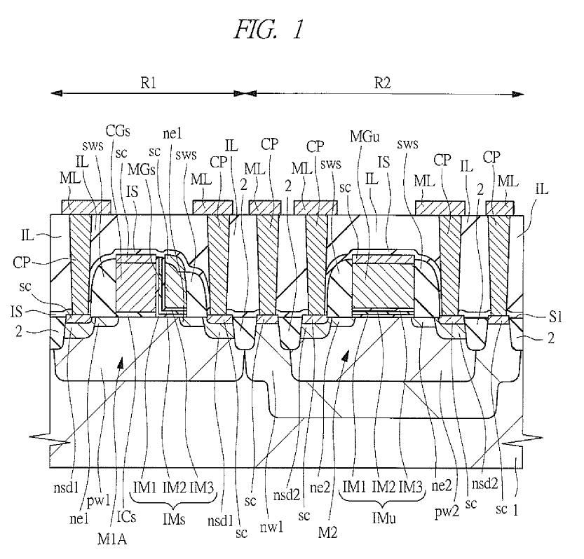

First, the structure of the nonvolatile semiconductor storage device shown in the first embodiment will be described below with reference to FIG. 1. FIG. 1 is a cross sectional view showing a principal part of a nonvolatile semiconductor storage device according to the first embodiment, in which the two types of memory cells are embedded.

The nonvolatile semiconductor storage device includes a silicon substrate (semiconductor substrate) 1 made of single crystal silicon (Si), and respective nonvolatile memory cells described in detail below are formed on this silicon substrate 1. In the first embodiment, the conductivity type of the silicon substrate 1 is p type (first conductivity type). For example, the p type is a state that contains a group III element such as boron (B) more than a group V element in silicon made of a group IV element, and it represents a conductivity type of a semiconductor material where the majority carriers are holes. Hereinafter, the same is true with respect to the p conductivity type, including the semiconductor region.

A main surface S1 of the silicon substrate 1 has a first region R1 and a second region R2 defined by separating portions 2. The separating portion 2 has a so-called STI (Shallow Trench Isolation) structure in which an insulating film such as a silicon oxide film is filled in a shallow trench formed in the main surface S1 of the silicon substrate 1. Then, a split-gate memory cell (first storage element) M1A is disposed in the first region R1 and a single-gate memory cell (second storage element) M2 is disposed in the second region R2. The respective structures will be described in detail below.

First, the structure of the split-gate memory cell M1A disposed in the first region R1 on the main surface S1 of the silicon substrate 1 will be described. The split-gate memory cell M1A is disposed in a first p well pw1 that is a p type semiconductor region formed in the first region R1 of the main surface S1 of the silicon substrate 1. A p type impurity concentration of this first p well pw1 is higher than that of the silicon substrate 1.

The split-gate memory cell M1A has two gate electrodes formed on the main surface S1 of the silicon substrate 1, that is, a control gate electrode (first gate electrode) CGs and a sidewall memory gate electrode (second gate electrode) MGs. These electrodes are, for example, conductive films mainly made of polycrystalline silicon (polysilicon).

The control gate electrode CGs is formed on the main surface S1 of the silicon substrate 1 via a control gate insulating film (first gate insulating film) ICs. The control gate insulating film ICs is an insulating film mainly made of, for example, silicon oxide.

Also, the sidewall memory gate electrode MGs is formed on the main surface S1 of the silicon substrate 1 via a charge trapping film (charge trapping insulating film) IMs. This charge trapping film IMs includes a first insulating film IM1, a second insulating film IM2, and a third insulating film IM3. The second insulating film IM2 is disposed so as to be sandwiched between the first insulating film IM1 and the third insulating film IM3, and the first insulating film IM1, the second insulating film IM2, and the third insulating film IM3 are disposed in this order from the side close to the main surface S1 of the semiconductor substrate 1.

Furthermore, the second insulating film IM2 is an insulating film having a function to store electric charge, and for example, it is an insulating film mainly made of silicon nitride with a thickness of 5 to 10 nm. Also, the first insulating film IM1 and third insulating film IM3 that sandwich the second insulating film IM2 are insulating films having a function to prevent leakage of electric charge stored in the second insulating film IM2 to outside. The first insulating film IM1 is an insulating film mainly made of silicon oxide with a thickness of, for example, 4 to 6 nm, and the third insulating film IM3 is an insulating film mainly made of silicon oxide with a thickness of, for example, 5 to 9 nm.

The control gate electrode CGs and the sidewall memory gate electrode MGs are adjacently disposed to each other in a state of being electrically isolated from each other. In the split-gate memory cell M1A of the first embodiment, the sidewall memory gate electrode MGs is formed so as to cover the sidewall of the control gate electrode CGs. The charge trapping film IMs formed between the main surface S1 of the silicon substrate 1 and the sidewall memory gate electrode MGs is also formed between the control gate electrode CGs and the sidewall memory gate electrode MGs in an integrated manner. Therefore, the control gate electrode CGs and the sidewall memory gate electrode MGs are adjacently disposed to each other in a state of being electrically isolated from each other by the charge trapping film IMs.

A sidewall spacer sws is formed on the sidewalls of the control gate electrode CGs and the sidewall memory gate electrode MGs. The sidewall spacer sws is made of, for example, a silicon oxide film and is formed for insulation so that both the electrodes do not contact with other wires and others.

An n type extension region ne1 is formed on the silicon substrate 1 just under the sidewall spacer sws. The n type extension region ne1 is a semiconductor region whose conductivity type is n type (second conductivity type). The n type is a state that contains a group V element such as phosphorus (P) and arsenic (As) more than a group III element in silicon made of a group IV element, and it represents a conductivity type of a semiconductor material where the majority carriers are electrons. Hereinafter, the same is true with respect to the n conductivity type. The n type extension region ne1 is formed for exchanging electrons with the inversion layer formed in the silicon substrate 1 under the control gate electrode CGs and the sidewall memory gate electrode MGs during the memory operation of the split-gate memory cell M1A. Accordingly, the n type impurity concentration and junction depth thereof are determined depending on the operating characteristics requested for the split-gate memory cell M1A.

In a region planarly included in the first p well pw1, an n type source/drain region nsd1 is formed in the main surface S1 of the silicon substrate 1 located laterally below the sidewall spacer sws. The n type source/drain region nsd1 is a semiconductor region whose conductivity type is n type. Also, the n type source/drain region nsd1 is formed so as to be electrically connected to the n type extension region ne1 for enabling the smooth electron exchange between the region and an external conductive portion. Therefore, the n type impurity concentration of the n type source/drain region nsd1 is higher than that of the n type extension region ne1.

The double structure of the n type extension region ne1 and the n type source/drain region nsd1 as shown above is a structure usually adopted in the MIS transistor, and it is referred to as an LDD (Lightly Doped Drain) structure. This is the structure for suppressing the decrease in reliability caused by the miniaturization of the MIS transistor. Hereinafter, the same is true with respect to the LDD structure.

In the split-gate memory cell M1A of the first embodiment, terminals that require electrical conduction from outside are the control gate electrode SGs, the sidewall memory gate electrode MGs, and the n type source/drain region nsd1. Accordingly, a silicide layer sc with a low resistance value is formed on the surfaces of these terminals, thereby realizing ohmic contact with the external wiring to be described later. The silicide layer sc is made of a compound of metal and silicon, and for example, cobalt silicide, nickel silicide or the like is used.

The basic structure of the split-gate memory cell M1A of the nonvolatile semiconductor storage device of the first embodiment has been described above. This structure is the same as the structure of the split-gate memory cell Kax shown in FIG. 29 studied by the present inventors. Accordingly, the split-gate memory cell M1A of the first embodiment can perform a high-speed memory operation. Detailed applications will be described later.

Second, the structure of the single-gate memory cell M2 disposed in the second region R2 on the main surface S1 of the silicon substrate 1 will be described. The single-gate memory cell M2 is disposed in a second p well (second semiconductor region) pw2 that is a p type semiconductor region formed in the second region R2 of the main surface S1 of the silicon substrate 1. A p type impurity concentration of this second p well pw2 is higher than that of the silicon substrate 1.

The single-gate memory cell M2 has a single memory gate electrode (third gate electrode) MGu formed on the main surface S1 of the silicon substrate 1 via a charge trapping film (charge trapping insulating film) IMu. The single memory gate electrode MGu is, for example, a conductive film mainly made of polycrystalline silicon.

In the single-gate memory cell M2 of the first embodiment, materials constituting the charge trapping film IMu may be the same as those of the charge trapping film IMs of the split-gate memory cell M1A. More specifically, the charge trapping film IMu has the first insulating film IM1, the second insulating film IM2, and the third insulating film IM3 formed in this order from the side close to the main surface S1 of the silicon substrate 1. The respective functions and characteristics of these three-layer insulating films are the same as those of the charge trapping film IMs of the split-gate memory cell M1A described above, and thus the detailed descriptions thereof will be omitted here.

The sidewall spacer sws similar to that of the split-gate memory cell M1A is formed on the sidewall of the single memory gate electrode MGu.

In the single-gate memory cell M2, an n type extension region ne2 is formed in the silicon substrate 1 just under the sidewall spacer sws. The n type extension region ne2 is a semiconductor region whose conductivity type is n type. The n type extension region ne2 is formed for exchanging electrons with the inversion layer formed in the silicon substrate 1 under the single memory gate electrode MGu during the memory operation of the single-gate memory cell M2. Accordingly, the n type impurity concentration and junction depth thereof are determined depending on the characteristics requested for the single-gate memory cell M2.

In a region planarly included in the second p well pw2, an n type source/drain region nsd2 is formed in the main surface S1 of the silicon substrate 1 located laterally below the sidewall spacer sws. The n type source/drain region nsd2 is a semiconductor region whose conductivity type is n type. Also, the n type source/drain region nsd2 is formed so as to be electrically connected to the n type extension region ne2 for enabling the smooth electron exchange between the region and an external conductive portion. Therefore, the n type impurity concentration of the n type source/drain region nsd2 is higher than that of the n type extension region ne2.

In the single-gate memory cell M2 of the first embodiment, terminals that require electrical conduction from outside are the single memory gate electrode MGu and the n type source/drain region nsd2. Therefore, the silicide layer sc is formed on the surfaces of these terminals. The silicide layer sc of the single-gate memory cell M2 is formed for the same purpose and with the same structure as those of the above-described split-gate memory cell M1A.

The basic structure of the single-gate memory cell M2 of the nonvolatile semiconductor storage device of the first embodiment has been described above. This structure is the same as the structure of the single-gate memory cell Kcx shown in FIG. 33 studied by the present inventors. Accordingly, the single-gate memory cell M2 of the first embodiment has high write and erase endurance. Detailed applications will be described later.

Also, in the nonvolatile semiconductor storage device of the first embodiment, an etch stop insulating film IS and an interlayer insulating film IL are formed in this order on the main surface S1 of the silicon substrate 1 so as to cover the above-described two memory cells M1A and M2. In addition, a contact plug CP is formed so as to penetrate through the etch stop insulating film IS and the interlayer insulating film IL. Furthermore, a wiring layer ML is formed on the interlayer insulating film IL so as to be electrically connected to the contact plug CP.

The interlayer insulating film IL is formed for the insulation of the contact plug CP, the wiring layer ML and others, and it is, for example, an insulating film mainly made of silicon oxide. Also, the etch stop insulating film IS is an insulating film with high selectivity for the interlayer insulating film IL in the anisotropic etching for forming the contact plug CP, and it is formed for the purpose of applying the so-called SAC (Self Align Contact) technique. The etch stop insulating film IS is, for example, an insulating film mainly made of silicon nitride.

The contact plug CP is, for example, a conductive film mainly made of tungsten (W). Also, as a barrier film for preventing chemical reaction between the tungsten and the silicon substrate 1, a conductive film mainly made of titanium nitride may be formed at the interface between the silicon substrate 1 and tungsten and the interface between the interlayer insulating film IL and tungsten. The contact plug CP is electrically connected to the silicide layer sc formed on each of the elements to be the terminals of the split-gate memory cell M1A and the single-gate memory cell M2. By this means, electrical conduction for causing both the memory cells M1A and M2 to perform memory operations can be provided.

The wiring layer ML is, for example, a conductive film mainly made of aluminum (Al) or copper (Cu). Although only one layer of the wiring layer ML is indicated here for simplification, multi-layer wirings composed of the same plugs (via plug) and wires are formed in the upper layers. This wiring layer ML has the desired circuit pattern on the interlayer insulating film IL, thereby realizing the circuit configuration required for the nonvolatile semiconductor storage device.

As described above, the nonvolatile semiconductor storage device of the first embodiment has two memory cells with different structures on the same silicon substrate 1. More specifically, the split-gate memory cell M1A that can operate at high speed is provided in the first region R1 and the single-gate memory cell M2 with high write and erase endurance is provided in the second region R2.

As described above, a nonvolatile semiconductor storage device that can achieve both the high speed performance and the high write and erase endurance that are in a trade-off relation can be constituted by embedding two types of memory cells on the same silicon substrate 1. For example, there may be a case where the first information to be rewritten at a relatively high speed and the second information to be rewritten relatively frequently are processed at the same time while they are being stored in a nonvolatile memory. At this time, if only the memory cells that operate based on the same mechanism are used, it is difficult to achieve both the high-speed performance and high write and erase endurance because they are in the trade-off relation.

In such a case, in the nonvolatile semiconductor storage device according to the first embodiment, the split-gate memory cell M1A is applied as a memory cell for storing the first information that requires high-speed performance, and the single-gate memory cell M2 is applied as a memory cell for storing the second information that requires high write and erase endurance. For example, the first information includes program information and the like for causing a logic circuit to perform arithmetic operation, and the second information includes data information and the like necessary for operation.

By embedding the split-gate memory cell M1A and single-gate memory cell M2 together in this manner, it is possible to realize a nonvolatile memory that can store the information that needs to be read at high speed and the information that needs to be rewritten frequently. As a result, the performance of the nonvolatile semiconductor storage device can be improved.

Also, as described above, the single-gate memory cell M2 is disposed in the second p well pw2 in the second region R2 of the silicon substrate 1. In the nonvolatile semiconductor storage device of the first embodiment, this second p well is formed in the first n well (first semiconductor region) nw1 that is an n type semiconductor region. More specifically, the second p well pw2 that has the same conductivity type as the silicon substrate 1 is electrically isolated from the silicon substrate 1 by the first n well nw1. Also, the silicide layer sc, the contact plug CP, and the wiring layer ML are formed for the first n well nw1, and the electric conduction can be provided.

By forming the single-gate memory cell M2 in the second p well pw2 with the structure as described above, it is possible to prevent the voltage applied to the silicon substrate 1 from being directly applied to the single-gate memory cell M2. By this means, even when two types of memory cells that operate based on different mechanisms and peripheral circuits are embedded on the same substrate like in the first embodiment, the substrate voltages can be applied independently from each other. More specifically, memory characteristics can be optimized independently from the substrate voltage to be applied to the peripheral circuit and others. As a result, the performance of the nonvolatile semiconductor storage device can be improved. The well structure as described above is sometimes referred to as a triple well structure.

Also, in the foregoing descriptions, only a three-layer structure in which an insulating film (second insulating film IM2) mainly made of silicon nitride is sandwiched between insulating films (first insulating film IM1 and third insulating film IM3) mainly made of silicon oxide is shown as an example of the charge trapping films IMs and IMu for storing electric charge in both the memory cells M1A and M2.

In the first embodiment, the second insulating film IM2 having a function to store electric charge may be an insulating film mainly made of metal oxide. The metal oxide to be used here is desirably a material having higher relative dielectric constant than silicon oxide (High-k material) for the following reasons.

Both the memory cells M1A and M2 are operated as the MIS transistors in, for example, read operation. At this time, the charge trapping films IMs and IMu function as gate insulating films, and therefore, it is preferable that the thicknesses of the charge trapping films IMs and IMu are not so large in consideration of the reading speed. On the other hand, from the standpoint of charge retention characteristic, it is preferable that the second insulating film IM2 for accumulating electric charge has a large thickness in consideration of the spatial capacity.

In such a trade-off relation, the equivalent oxide thickness can be reduced by using an insulating film mainly made of metal oxide having higher relative dielectric constant than silicon oxide as a gate insulating film. In both the memory cells M1A and M2 of the first embodiment, the film having a function to store electric charge in the charge trapping films IMs and IMs is the second insulating film IM2. Also, the case where silicon nitride is used as the second insulating film IM2 has been shown. Therefore, it is more preferable that a material having higher relative dielectric constant than silicon nitride from among the materials having higher relative dielectric constant than silicon oxide is used for this second insulating film IM2. This is because the second insulating film IM2 thicker than that made of a silicon nitride film can be formed in expectation of the improvement in the retention characteristic. Accordingly, in the case where higher-speed operation and further improved charge retention characteristic are required in both the memory cells M1A and M2 of the first embodiment, an insulating film mainly made of metal oxide having higher relative dielectric constant than a silicon nitride film is preferably used as the second insulating film IM2. As a result, the performance of the nonvolatile semiconductor storage device can be further improved.

According to the quantitative studies made by the present inventors, when an insulating film mainly made of metal oxide is used, the second insulating film IM2 can have a thickness of 8 to 12 nm. In other words, the thickness of the second insulating film IM2 can be increased compared with 5 to 10 nm in the case where a silicon nitride film is used as the second insulating film IM2. Also, hafnium oxide (hafnia) is preferably used as the metal oxide having higher relative dielectric constant than silicon oxide. This is because, according to the studies made by the present inventors, application of hafnium oxide to a gate insulating film of a MIS transistor is now in a practical use stage and hafnium oxide has enough achievement as an insulating film on a semiconductor substrate. As a result, the performance of the nonvolatile semiconductor storage device can be further improved.

In the first embodiment, an insulating film mainly made of aluminum oxide (alumina) may be used as the third insulating film IM3 formed on the side close to the memory gate electrodes MGs and MGu as an insulating film having a function to prevent leakage of the electric charge accumulated in the second insulating film IM2 to outside. As described above, electrons are accumulated in the charge trapping films IMs and IMu in, for example, write operation. In order to accumulate the electrons, relatively high positive voltage is applied to both the memory gate electrodes MGs and MGu. At this time, there is the possibility that holes are injected from both the memory gate electrodes MGs and MGu. If holes are injected into the charge trapping films IMs and IMu in the write operation, the holes are recombined with the electrons injected from the silicon substrate 1, so that a desired electric charge cannot be accumulated.

Here, as compared with a valence band edge of silicon oxide, a valence band edge of aluminum oxide has a larger energy difference from a valence band edge of silicon. Therefore, by disposing an insulating film mainly made of aluminum oxide at the interface between both the memory gate electrodes MGs and MGu and the charge trapping films IMs and IMu, injection of holes becomes more difficult. More specifically, it is more preferable to use an insulating film mainly made of aluminum oxide as the third insulating film IM3. As a result, the performance of the nonvolatile semiconductor storage device can be further improved.

Next, the manufacturing process of the nonvolatile semiconductor storage device of the first embodiment will be described in detail. In particular, in the nonvolatile semiconductor storage device of the first embodiment, memory cells with different structures need to be formed on the same substrate as described above. If these memory cells are formed in entirely different processes, the number of processes remarkably increases, and there arise new problems of reduction in productivity such as the decrease in manufacturing yield and the manufacturing cost increase. Thus, a manufacturing technique for forming memory cells with different structures in the same process without increasing the number of processes will be shown in the first embodiment.

Note that, in the following, a process in which a MIS transistor with a general structure is also formed at the same time will be described on the assumption that peripheral circuits are embedded in addition to the memory cells. Further, the detailed description of the structural effects of the components of nonvolatile semiconductor storage device of the first embodiment formed in the respective processes will be omitted here because the structural effects are as described above. In other words, in the following, only the effects of the manufacturing technique will be described in detail.

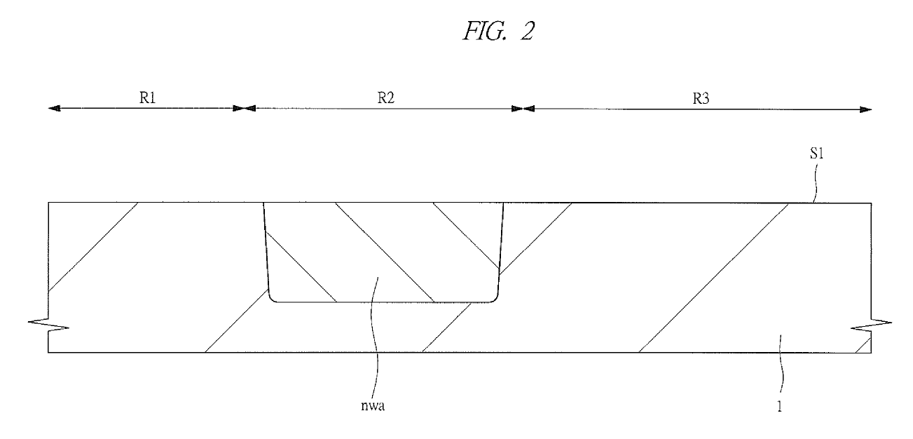

As shown in FIG. 2, a silicon substrate 1 is prepared. This silicon substrate 1 is semiconductor mainly made of single crystal silicon, and is a wafer-like semiconductor substrate containing about 10¹⁶/cm³ of boron to show the p conductivity type. This figure shows the principal part thereof in an enlarged manner. Also, the main surface S1 of the silicon substrate 1 has a first region R1, a second region R2, and a third region R3. In the first embodiment, the split-gate memory cell M1A of FIG. 1 described above is formed in the first region R1, the single-gate memory cell M2 of FIG. 1 described above is formed in the second region R2, and a MIS transistor is formed in the third region R3.

In the second region R2 of the silicon substrate 1, an n type first diffusion layer nwa is selectively formed. This diffusion layer can be formed by implanting phosphorus ion into the second region R2 from the main surface S1 side of the silicon substrate 1 by using, for example, the ion implantation and then performing the heat treatment. Also, the above-described process is performed so that the n type impurity concentration of the n type first diffusion layer nwa becomes approximately 10¹⁷/cm³. In order to selectively form the n type first diffusion layer nwa in the second region R2 here, it is necessary to form an ion implantation mask on the silicon substrate 1 in the other regions. For example, a photoresist film (not shown) patterned in a series of photolithography is used as the ion implantation mask. Hereinafter, the process of performing the selective ion implantation is the same unless otherwise stated.

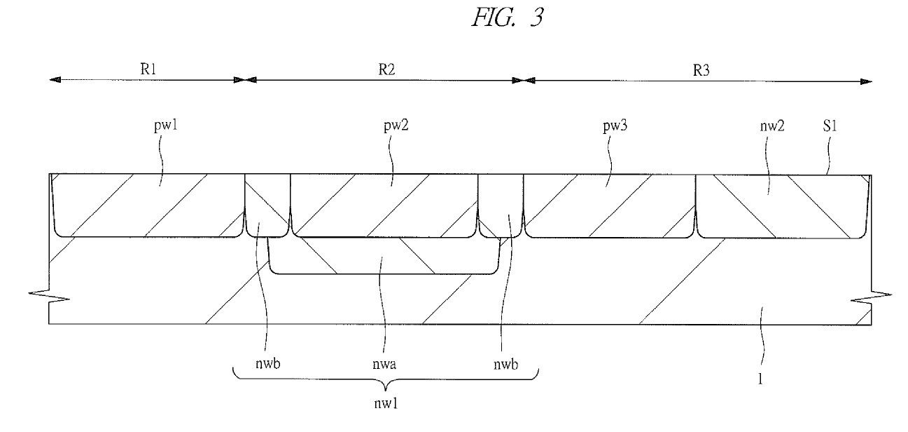

Next, as shown in FIG. 3, a first p well pw1, a second p well pw2, and a third p well pw3 that are p type semiconductor regions are selectively formed in desired regions of the main surface S1 of the silicon substrate 1 by, for example, the ion implantation. The desired regions of the main surface S1 of the silicon substrate 1 mentioned here concretely mean the following regions.

First, the first p well pw1 is formed in the first region R1. Also, the second p well pw2 is formed in the second region R2 so that it is included in the n type first diffusion layer nwa when viewed in a plane of the main surface S1 and becomes shallower than the n type first diffusion layer nwa when viewed along the depth direction of the silicon substrate 1. Further, the third p well pw3 is formed in a part of the third region R3. In the subsequent processes, the split-gate memory cell M1A of FIG. 1 is formed in the first p well pw1, the single-gate memory cell M2 of FIG. 1 is formed in the second p well pw2, and the n channel MIS transistor is formed in the third p well pw3.

Also, the p type impurity concentrations of the first p well pw1, the second p well pw2, and the third p well pw3 are higher than the p type impurity concentration of the silicon substrate. If the species, supply amount (dose amount), and implantation energy of the impurity ion to be implanted to form the first p well pw1, the second p well pw2, and the third p well pw3 are the same, the ion implantation process to form the first to third wells pw1, pw2 and pw3 can be performed by the same process. Also, if the heat treatment conditions after the ion implantation are the same, the heat treatment thereof can be performed by the same process. These processes are preferably performed by the same process as far as possible because the number of manufacturing processes can be reduced. Hereinafter, the same is true with respect to the process to form a plurality of semiconductor regions.

Subsequently, the n type second diffusion layer nwb and the second n well nw2 that are n type semiconductor regions are selectively formed in the desired regions of the main surface S1 of the silicon substrate 1 by, for example, the ion implantation. The desired regions of the main surface S1 of the silicon substrate 1 mentioned here concretely mean the following regions.

First, the n type second diffusion layer nwb is formed in the second region R2 so as to surround the circumference of the second p well pw2 when viewed in a plane of the main surface S1 and so as to have an n type impurity concentration equivalent to that of the n type first diffusion layer nwa. By this means, the n type second diffusion layer nwb and the previously formed n type first diffusion layer nwa are disposed between the second p well pw2 and the silicon substrate 1. Accordingly, the second p well pw2 is electrically isolated from the silicon substrate 1 by the n type first diffusion layer nwa and the n type second diffusion layer nwb. More specifically, the n type first diffusion layer nwa and the n type second diffusion layer nwb constitute the first n well nw1 described with reference to FIG. 1.

Also, the second n well nw2 is formed in a part of the third region R3 so as not to planarly overlap the previously formed third p well pw3. The p channel MIS transistor is formed in this second n well nw2 in the subsequent processes.

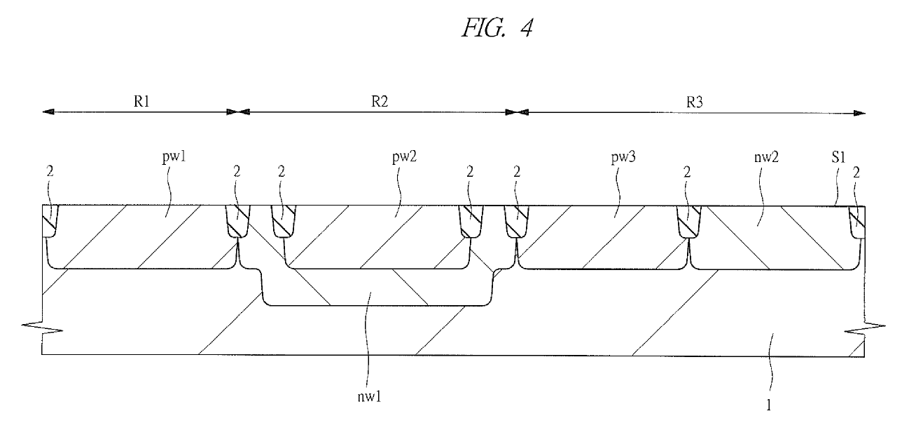

Next, as shown in FIG. 4, the separating portion 2 is formed in the main surface S1 of the silicon substrate 1. First, an insulating film is formed on the main surface S1 of the silicon substrate 1, and the insulating film in the location where the separating portion 2 is to be formed is removed (opened) (not shown). For example, the photolithography and anisotropic etching are used for this. Then, a trench with a depth of about 300 nm from the main surface S1 is formed by applying anisotropic etching to the main surface S1 of the silicon substrate 1 with using the insulating film as an etching mask. Then, by using a dry thermal oxidation, a CVD (Chemical Vapor Deposition) method using TEOS (Tetra Ethyl Ortho Silicate) and ozone (O₃) as a raw material and others in combination, a silicon oxide film is formed on the main surface S1 including the inside of the trench. Thereafter, unnecessary silicon oxide film is removed by, for example, a CMP (Chemical Mechanical Polishing) method and others. In this manner, the separating portion 2 with the STI structure in which a silicon oxide film whose surface is almost identical to the main surface S1 of the silicon substrate 1 is embedded can be formed.

In the first embodiment, for example, the separating portion 2 is formed in a boundary portion of the wells formed in the previous process such as the boundary between the first region R1 and the second region R2. The separating portion 2 has the STI structure in which an insulator is embedded in a shallow trench, and it is formed to isolate and separate each of the wells so as to define the active regions.

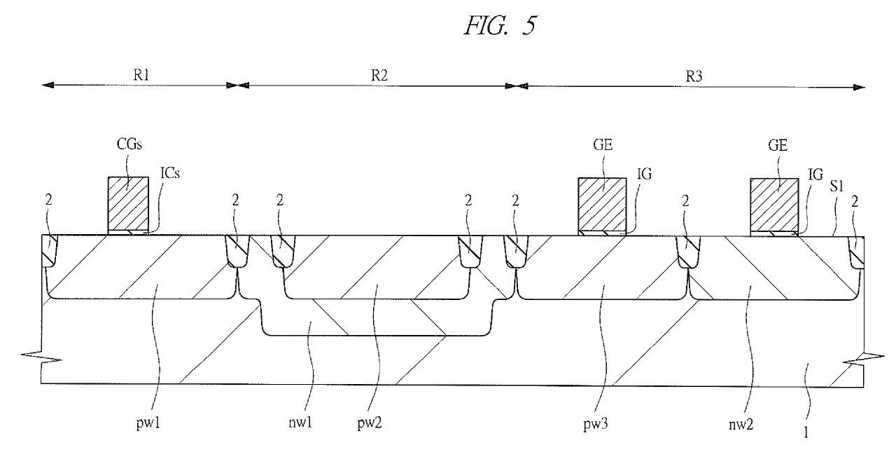

Next, as shown in FIG. 5, the control gate electrode CGs is formed on the main surface S1 of the silicon substrate 1 in the first region R1 via the control gate insulating film ICs. Also, in each of the third p well pw3 and the second n well nw2 in the third region R3, the gate electrode GE is formed on the main surface S1 of the silicon substrate 1 via the gate insulating film IG. The control gate insulating film ICs and the gate insulating film IG are, for example, insulating films mainly made of silicon oxide, and the control gate electrode CGs and the gate electrode GE are, for example, conductive films mainly made of polycrystalline silicon.

In the first embodiment, the control gate electrode CGs and the gate electrode GE are formed in the same process. Also, the control gate insulating film ICs and the gate insulating film IG are formed in the same process. The method thereof will be described in detail below.

First, a silicon oxide film with a thickness of about 2 nm is formed on the main surface S1 of the silicon substrate 1 by, for example, the thermal oxidation and others. Then, a polycrystalline silicon film with a thickness of about 150 nm is formed thereon by, for example, the CVD method and others. Thereafter, the control gate electrode CGs is formed in the desired location of the first region R1 and the gate electrode GE is formed in the desired location of the third region R3 at a time, respectively, by applying the anisotropic etching to the polycrystalline silicon film with using the photoresist film patterned by the photolithography and the like as the etching mask. Then, the control gate insulating film ICs is formed under the control gate electrode CGs and the gate insulating film IG is formed under the gate electrode GE at a time, respectively, by applying the anisotropic etching to the silicon oxide film with using the same photoresist film as the etching mask.

Note that impurities are introduced to the control gate electrode CGs and the gate electrode GE so that they have desired characteristics. Specifically, for a gate electrode of an n channel MIS transistor, a group V impurity element such as phosphorus is introduced, and for a gate electrode of a p channel MIS transistor, a group III impurity element such as boron is introduced. The impurity introduction into the gate electrodes is performed by selectively implanting ions after the polycrystalline silicon film is formed in the above-descried process. Hereinafter, unless specifically mentioned, the process for forming gate electrodes (including control gate electrodes of memory cell and memory gate electrodes) includes the process for introducing impurities through the same process.

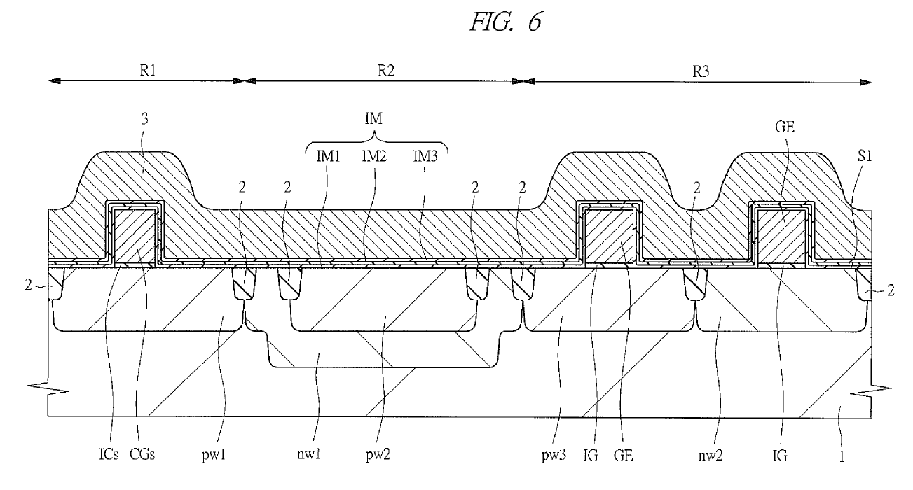

Next, as shown in FIG. 6, the charge trapping film IM is formed so as to cover the main surface S1 of the silicon substrate 1 in the first region R1, the second region R2, and the third region R3. In this case, the first insulating film IM1, the second insulating film IM2, and the third insulating film IM3 are formed in this order as the charge trapping film IM. The functions of the respective insulating films are as described with reference to FIG. 1.

In the first embodiment, first, the main surface S1 of the silicon substrate 1 is oxidized by, for example, the thermal oxidation and others. At this time, the side surfaces and upper surfaces of the control gate electrode CGs and the gate electrode GE are also oxidized. By this means, the first insulating film IM1 mainly made of silicon oxide with a thickness of approximately 4 to 6 nm is formed. Next, an insulating film mainly made of silicon nitride with a thickness of approximately 5 to 10 nm is formed as the second insulating film IM2 by, for example, the CVD method and others. This silicon nitride film is also formed on the entire main surface S1 of the silicon substrate 1. Next, the surface of the above-described silicon nitride film is oxidized by, for example, the thermal oxidation and others. By this means, the third insulating film IM3 mainly made of silicon oxide with a thickness of approximately 5 to 9 nm is formed.

Also, as described with reference to FIG. 1, an insulating film mainly made of metal oxide such as hafnium oxide having higher relative dielectric constant than silicon oxide is formed as the second insulating film IM2 in some cases. In this case, a metal oxide film with a thickness of approximately 8 to 12 nm is formed by, for example, an evaporation method and others. In addition, as described with reference to FIG. 1, an insulating film mainly made of aluminum oxide is formed as the third insulating film IM3 in some cases. In this case, aluminum oxide with a thickness of approximately 5 to 9 nm is formed by, for example, the evaporation method, in particular, by an ALD (Atomic Layer Deposition) method.

Hereinafter, in the first embodiment, the charge trapping film IM composed of the three layers of the insulating films IM1, IM2 and IM3 will be described and illustrated collectively.

Subsequently, a first conductive film 3 is formed on the charge trapping film IM. A polycrystalline silicon film is formed as the first conductive film 3 by, for example, the CVD method and others. As described later in detail, the first conductive film 3 made of a polycrystalline silicon film is processed by the anisotropic etching to be a memory gate electrode in a memory cell. In the first embodiment, for example, phosphorus is introduced into the first conductive film 3 as an impurity.

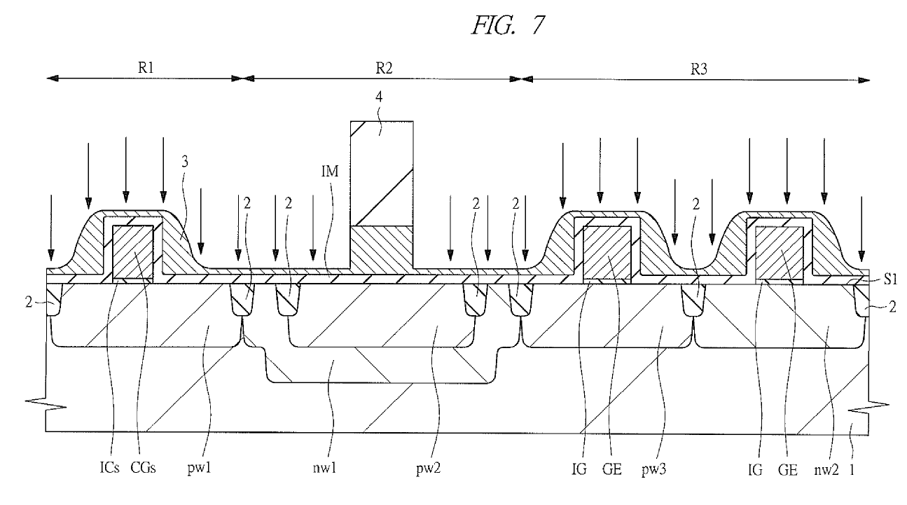

In the next process, as shown in FIG. 7, anisotropic etching is applied to the first conductive film 3. In this case, anisotropic etching where etching is mainly performed in the direction intersecting with the main surface S1 of the silicon substrate 1 is applied. When the anisotropic etching as described above is applied, the first conductive film 3 remains in self-alignment in a shape of covering the sidewall of the control gate electrode CGs protruding on the main surface S1 of the silicon substrate 1 in the first region R1. In the subsequent processes, this conductive film becomes the sidewall memory gate electrode MGs of the split-gate memory cell M1A shown in FIG. 1. Similarly, the first conductive film 3 remains also on the sidewall of the gate electrode in the third region R3 in self-alignment.

Furthermore, in the first embodiment, the first conductive film 3 remains in a part of the second region R2. This part of the conductive film becomes the single memory gate electrode MGu of the single-gate memory cell M2 shown in FIG. 1. Therefore, the first conductive film 3 is processed by the anisotropic etching so that it remains in a part of the second p well pw2 in the second region 2 when viewed in a plane of the main surface S1. However, since the shape shown above cannot be formed in self-alignment, an etching mask to prevent the exposure to the anisotropic etching of the first conductive film 3 needs to be formed in the second region R2.

In the first embodiment, a photoresist film 4 is formed in a part of the second region R2. The photoresist film 4 is formed by, for example, a series of photolithography. By applying the above-described anisotropic etching to the first conductive film 3 with using this photoresist film 4 as the etching mask, the first conductive film 3 can be left on the sidewall of the control gate electrode CGs in the first region R1 and in the lower part of the photoresist film 4 in the second region R2.

Here, the photoresist film 4 formed as the etching mask for leaving the first conductive film 3 in the second region R2 in the above-described manner is desirably formed in the same process as the other photoresist films to be formed for other applications. This is because, if this process is specific to leave the first conductive film 3 in the second region R2, the total number of processes increases, and as a result, the reduction in productivity such as the decrease in manufacturing yield and the manufacturing cost increase is caused. The manufacturing method of the first embodiment uses the following processes to solve the problems above.

For example, in the split-gate memory cell M1A of FIG. 1 formed in the first region R1, it is necessary to form a contact plug CP for electrically connecting to the sidewall memory gate electrode MGs. However, in the first region R1, the first conductive film 3 is simply formed on the sidewall of the control gate electrode CGs in self-alignment, and thus the contact plug CP cannot be directly formed here. In such a case, an extraction portion is generally formed at a part of the first conductive film 3 which is electrically connected to the sidewall memory gate electrode MGs and is not related to the configuration of the memory element. More specifically, the part of the first conductive film 3 as described above is intentionally left widely, and the contact plug C is dropped there.

FIG. 8 shows a cross sectional view of a principal part in any of extending directions of the control gate electrode CGs as the fourth region R4 on the silicon substrate 1. The cross sectional view in the same process as FIG. 7 is shown here. In the first conductive film 3 to be removed by anisotropic etching, a part of the first conductive film 3 to be electrically connected to the sidewall memory gate electrode MGs (see FIG. 1) formed later needs to be intentionally left as the above-mentioned extraction portion in the fourth region R4. Specifically, of the first conductive films 3, the first conductive film 3 formed on the sidewall of the control gate electrode CGs on the side where the sidewall memory gate electrode MGs is to be disposed later is left so as to planarly extend over the lateral side of the control gate electrode CGs. Then, the photoresist film 4 needs to be formed in the above part as the etching mask for anisotropic etching.

As described above, the etching mask for forming the extraction portion of the sidewall memory gate electrode MGs is required even if the element to be formed on the silicon substrate 1 is only the split-gate memory cell M1A shown in FIG. 1. Thus, in the first embodiment, the photoresist film 4 for leaving the first conductive film 3 in the second region R2 of FIG. 7 is formed by using the same photomask as the etching mask for forming the extraction portion in the fourth region R4. By this means, the photoresist film 4 for leaving the first conductive film 3 in the second region R2 can be formed without increasing the number of processes. As a result, a high-performance memory cell can be formed without deteriorating the productivity of nonvolatile semiconductor storage device. The photoresist film 4 is removed after the desired etching is applied.

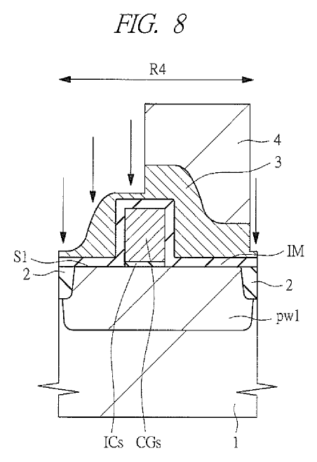

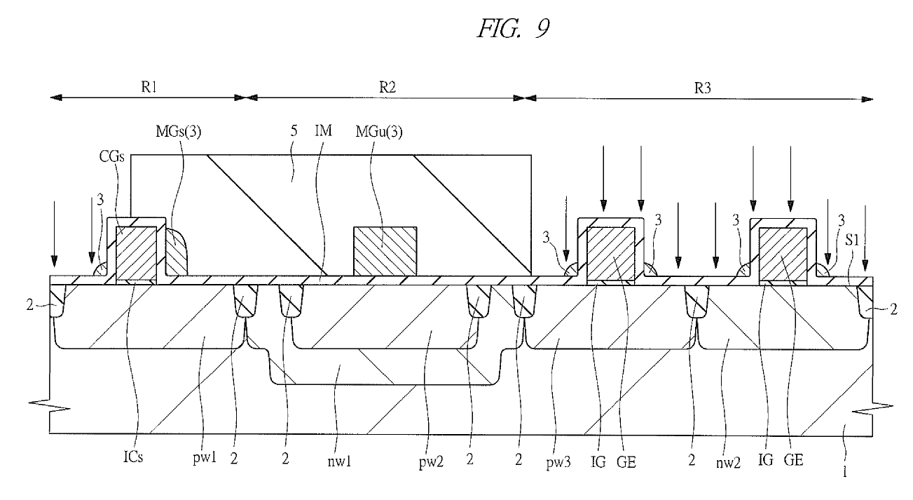

Through the processes described above, as shown in FIG. 9, the single memory gate electrode MGu is formed in the second region R2 so that it is disposed in the second p well when viewed in a plane of the main surface S1.

Then, unnecessary portions of the first conductive film 3 left in self-alignment by the above-described anisotropic etching are removed by etching. In the first embodiment, like in the nonvolatile semiconductor storage device shown in FIG. 1, one of the first conductive films 3 left on the sidewalls of the control gate electrode CGs is unnecessary in the first region R1. Furthermore, in the third region R3, all the first conductive films 3 left on the sidewalls of the gate electrodes GE are unnecessary.

Thus, a photoresist film 5 is formed so as to cover the first conductive film 3 left on one sidewall of the control gate electrode CGs in the first region R1 and the single memory gate electrode MGu in the second region R2. Then, the first conductive film 3 not covered with the photoresist film 5 is exposed to etching and removed by applying selective etching to the first conductive film 3 made of polycrystalline silicon with using the photoresist film 5 as the etching mask. Thereafter, the photoresist 5 is removed.

Through the processes described above, the sidewall memory gate electrode MGs is formed so as to cover one sidewall of the control gate electrode CGs in the first region R1. Also, the single memory gate electrode MGu is left in the second region R2.

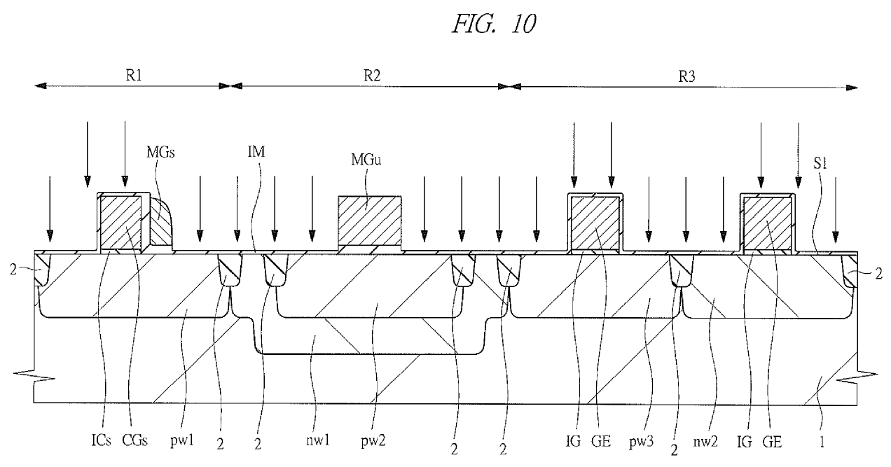

Next, as shown in FIG. 10, the charge trapping film IM exposed on the silicon substrate 1 is removed by applying etching for selectively removing the charge trapping film IM to the main surface S1 of the silicon substrate 1. Here, if the high selectivity for silicon is set as the etching condition, the etching is stopped when the charge trapping film IM is removed and the silicon substrate 1 made of polycrystalline silicon is exposed. Similarly, etching is stopped when the control gate electrode CGs or the single memory gate electrode MGu made of polycrystalline silicon is exposed.

Also, when the charge trapping film IM is removed under the etching condition of high selectivity for silicon as shown above, the sidewall memory gate electrode MGs and the single memory gate electrode MGu function as the etching mask. Therefore, the charge trapping film IM is etched to remain in the lower parts of the sidewall memory gate electrode MGs and the single memory gate electrode MGu.

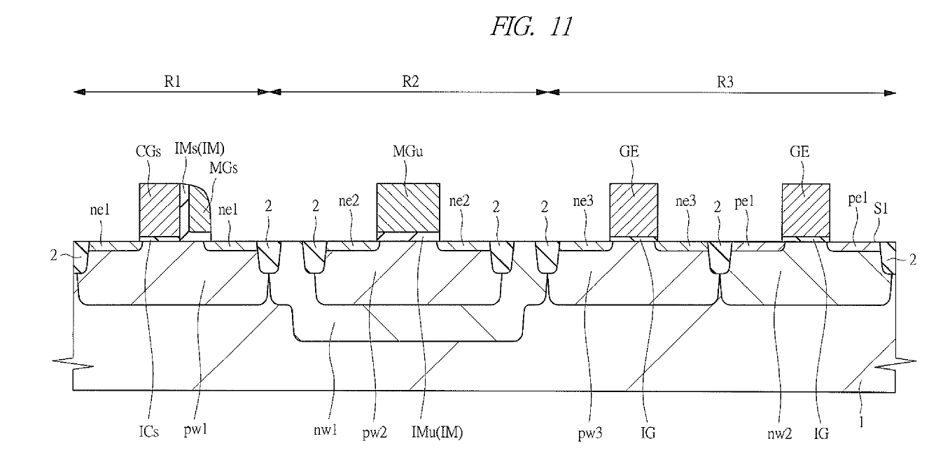

By applying the etching to the charge trapping film IM in the above-described manner, the charge trapping film IMs is formed between the sidewall memory gate electrode MGs and the silicon substrate 1 in the first region R1 as shown in FIG. 11. Also, this charge trapping film IMs is also formed between the control gate electrode CGs and the sidewall memory gate electrode MGs in an integrated manner. Moreover, in the second region R2, the charge trapping film IMu is formed between the single memory gate electrode MGu and the silicon substrate 1.

Subsequently, the desired impurity ion is implanted into the main surface S1 of the silicon substrate 1 by, for example, the ion implantation and others, and then thermal treatment is performed. At this time, the control gate electrode CGs and the sidewall memory gate electrode MGs in the first region R1, the single memory gate electrode MGu in the second region R2, and the gate electrode GE in the third region R3 function as the ion implantation mask.

In the first embodiment, the n type extension regions ne1 are formed by this process in the first p well pw1 laterally below the control gate electrode CGs and the sidewall memory gate electrode MGs in the first region R1. Also, the n type extension regions ne2 are formed in the second p well pw2 laterally below the single memory gate electrode MGs in the second region R2. In addition, in the third region R3, laterally below the gate electrodes GE, the n type extension regions ne3 are formed in the third p well pw3 and the p type extension regions pe1 are formed in the second n well nw2.

In general, MIS transistors that constitute a nonvolatile memory cell and MIS transistors that constitute a peripheral circuit differ in the roles and performances required for their extension regions. For example, as described with reference to FIG. 31, a relatively high voltage of approximately 5 V is applied to the MIS transistors that constitute the nonvolatile memory cell when information is written or erased. Therefore, the extension regions need to withstand the high voltage. In general, the withstand voltage of a semiconductor region depends on impurity concentration and distribution, and the withstand voltage is improved as the concentration becomes lower and the distribution becomes wider. However, in such low concentration and wide distribution, the performance of MIS transistors that constitute the peripheral circuit cannot be secured.

Accordingly, in the nonvolatile semiconductor storage device of the first embodiment, the n type extension regions ne1 and ne2 of the first region R1 and the second region R2 that form a nonvolatile memory cell and the n type extension regions ne3 of the third region R3 that form an MIS transistor for a peripheral circuit are formed in different processes because required characteristics are different. However, since semiconductor regions having various impurity concentrations and distributions need to be formed on the silicon substrate 1, any of these processes can be shared with the processes for forming the extension regions ne1 to ne3 and pe1, and the number of processes does not increases.

Next, as shown in FIG. 12, the sidewall spacer sws is formed so as to cover the sidewalls of the respective gate electrodes CGs, MGs, MGu and GE on the main surface S1 of the silicon substrate 1. For its formation, first, a silicon oxide film (not shown) is formed on the main surface S1 of the silicon substrate 1 by, for example, the CVD method using TEOS and ozone as a raw material. Then, anisotropic etching where etching is mainly performed in the direction intersecting with the main surface S1 of the silicon substrate 1 is applied to the silicon oxide film. By this means, the sidewall spacer sws made of a silicon oxide film is left in self-alignment so as to cover the sidewalls of the respective gate electrodes CGs, MGs, MGu and GE.

Subsequently, in the silicon substrate 1 laterally below the sidewall spacer sws formed in the process above, the n type source/drain regions nsd1 are formed in the first p well pw1 of the first region R1 and the n type source/drain regions nsd2 are formed in the second p well pw2 of the second region R2. Similarly, in the third region R3, the n type source/drain regions nsd3 are formed in the third p well pw3 and the p type source/drain regions psd2 are formed in the second n well nw2.

These are formed by, for example, implanting the desired impurity ion into the main surface S1 of the silicon substrate 1 by the ion implantation, and then performing thermal treatment. At this time, the respective gate electrodes CGs, MGs, MGu and GE and the sidewall spacer sws formed on the main surface S1 of the silicon substrate 1 function as the ion implantation mask, and the respective source/drain regions nsd1 to nsd3 and psd1 are formed in the regions in self-alignment.

Also, the extension regions ne1 to ne3 and pe1 have been formed in the main surface S1 of the silicon substrate 1 in the region where the above ion implantation mask is not formed. The above ion implantation process implants an impurity ion of the same conductivity type into these regions in a superimposed manner. Therefore, the source/drain regions and the extension regions formed in the same region (for example, n type source/drain regions nsd1 and n type extension region ne1) are electrically connected to each other.

Then, a silicide layer sc is formed on the surfaces of the gate electrodes CGs, MGs, MGu, and GE and the source/drain regions nsd1 to nsd3 and psd1. For its formation, first, a cobalt film (not shown) is deposited on the main surface S1 of the silicon substrate 1 by, for example, sputtering and the others, and then thermal treatment is performed at a certain temperature where the cobalt film and silicon react chemically (silicide reaction). By this means, cobalt silicide is formed in a region where the cobalt film and the silicon are in contact. Note that the cobalt silicide film thickness is controlled by the temperature and time of the thermal treatment. Lastly, the cobalt film left without contributing to the silicide reaction is removed, thereby forming the silicide layer sc made of a conductive film mainly made of cobalt silicide.

Note that the region where the above-described silicide reaction occurs is a region where the cobalt film and the silicon are in contact, and silicide reaction rarely occurs in a region where the cobalt film and silicon oxide are in contact. Therefore, the silicide layer sc is not formed on the sidewall spacer sws mainly made of a silicon oxide film and on the surface of the separating portion 2. Thus, the silicide layer sc is formed in self-alignment on the surfaces of the source/drain regions nsd1 to nsd3 and psd1 that are single crystal silicon and the surfaces of the gate electrodes CGs, MGs, MGu, and GE that are polycrystalline silicon.

Through the processes described above, the basic configuration of each element has been formed on the main surface S1 of the silicon substrate 1. More specifically, by the manufacturing processes of the first embodiment, a nonvolatile semiconductor storage device having a structure in which the split-gate memory cell M1A is disposed in the first p well pw1 of the first region R1 and the single-gate memory cell M2 is disposed in the second p well pw2 of the second region R2 has been formed. Further, in the third region R3, the n channel MIS transistor Qn (hereinafter simply referred to as “n type transistor”) is disposed in the third p well pw3 and the p channel MIS transistor Qp (hereinafter simply referred to as “p type transistor”) is disposed in the second n well nw2. The following is the processes for forming wirings to each of the elements.

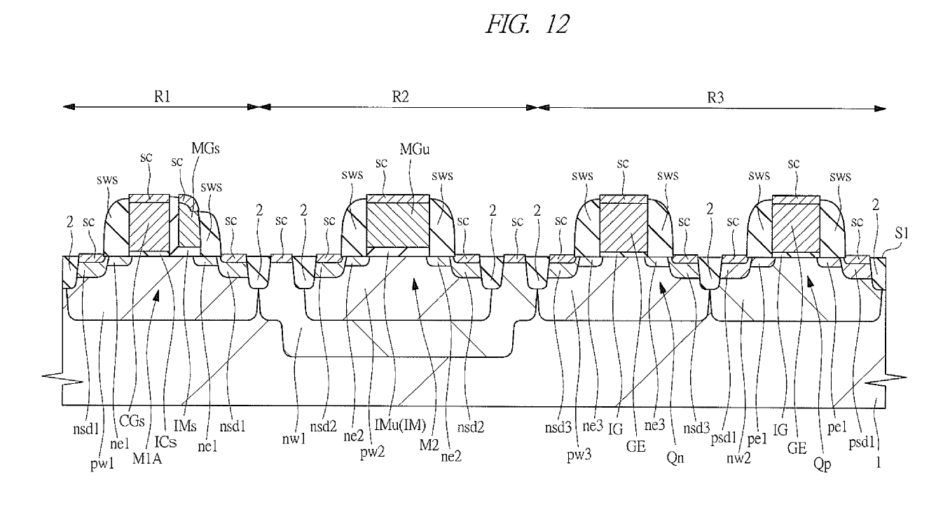

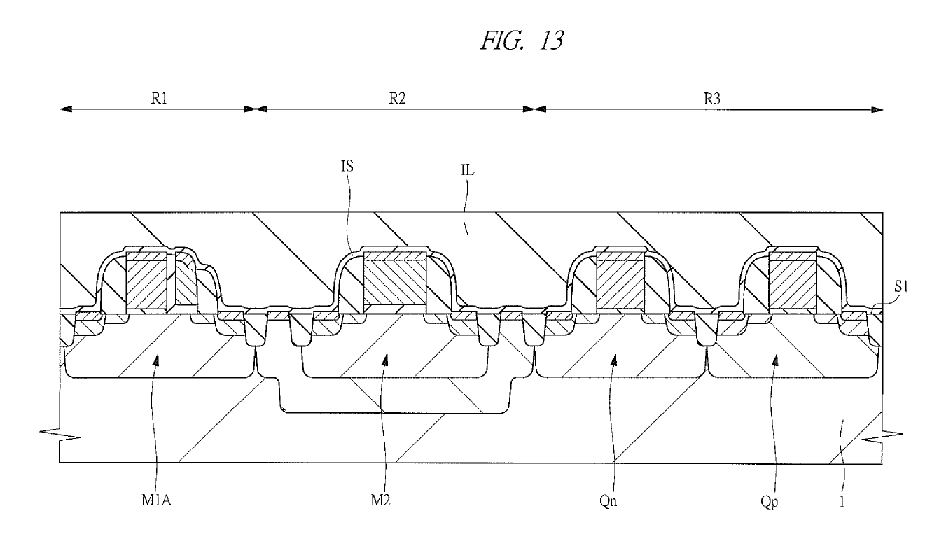

As shown in FIG. 13, an etch stop insulating film IS is formed on the main surface S1 of the silicon substrate 1 so as to cover the split-gate memory cell M1A, the single-gate memory cell M2, the n type transistor Qn, and the p type transistor Qp formed through the processes described above. Thereafter, an interlayer insulating film IL is formed so as to cover the etch stop insulating film IS. Here, a silicon nitride film is formed as the etch stopper layer IS and a silicon oxide film is formed as the interlayer insulating film IL by, for example, the CVD method and others. After forming the interlayer insulating film IL, the surface thereof is polished to be planarized by, for example, the CMP method and others.

Then, as shown in FIG. 14, contact holes CH are formed so as to penetrate through the interlayer insulating film IL and the etch stop insulating film IS to reach the silicide layers sC. The contact holes CH are formed for all the source/drain regions and all the gate electrodes formed on the surface of the silicon substrate 1.

Here, anisotropic etching is first applied to the interlayer insulating film IL with using a photoresist film (not shown) patterned by the photolithography and others as the etching mask. At this time, the interlayer insulating film IL is processed under the etching condition of sufficiently high selectivity for a silicon oxide film as compared with a silicon nitride film. By this means, the etching can be substantially stopped when the interlayer insulating film IL made of a silicon oxide film is etched and the etching reaches the etch stop insulating film IS made of a silicon nitride film. Therefore, it is possible to etch the interlayer insulating film IL at a high rate without being concerned about the damage on the silicon substrate 1 due to overetching.

Then, the etch stop insulating film IS is processed and etched under the etching condition of sufficiently high selectivity for a silicon nitride film as compared with the silicon oxide film, thereby forming the contact holes CH. As described above, in the manufacturing method of the first embodiment, a so-called SAC (Self Align Contact) technique for forming the contact holes CH in self-alignment is adopted.

Subsequently, contact plugs CP are formed by filling the contact holes CH with a conductive film. Here, a tungsten film (not shown) is formed entirely on the main surface S1 of the silicon substrate 1 by, for example, the sputtering method and others. Then, the tungsten film is removed to the same level as the surface of the interlayer insulating film IL by polishing the tungsten film by, for example, the CMP method and others. By this means, the contact plugs CP in which the tungsten film is filled are formed in the contact holes CH.

Next, wiring layers ML are formed on the contact plugs CP. The wiring layer ML is, for example, a conductive film such as aluminum and copper and is formed to connect the contact plugs CP conducted to respective elements. Only the wiring layers ML in one layer are shown for simplification here, but the similar plug (via plug) and wiring are repeatedly formed by a general multilayer interconnection technique in upper layers, thereby forming the desired circuit configuration.

As described above, by the technique of the first embodiment, two types of memory cells (split-gate memory cell M1A and single-gate memory cell M2) with different structures can be formed on the same substrate. Further, in the technique of the first embodiment, the above structures can be formed without introducing a new process and increasing the number of processes. As a result, the performance of the nonvolatile semiconductor storage device can be improved without reduction in productivity such as the decrease in manufacturing yield and the manufacturing cost increase.

According to the further studies made by the present inventors, there is the possibility that, with the improvement of memory cell performance and peripheral circuit scaling, miniaturization is required for the sidewall memory gate electrode MGs in the split-gate memory cell M1A shown in FIG. 1 in the direction horizontal to the main surface 1. As described with reference to FIG. 6 to FIG. 9, the sidewall memory gate electrode MGs is formed in self-alignment on the sidewall of the control gate electrode CGs when anisotropic etching is applied to the first conductive film 3.

At this time, according to the studies made by the present inventors, the size of the sidewall memory gate electrode MGs formed on the sidewall in self-alignment is determined by the height of the control gate electrode CGs. In other words, even when a first conductive film 3 of the same thickness is formed, the width in the planar direction of the first conductive film 3 covering the sidewall of the control gate electrode CGs changes if the height of the control gate electrode CGs differs. Therefore, it is possible to satisfy the request to reduce the size of the sidewall memory gate electrode MGs by adjusting the height of the control gate electrode CGs.

On the other hands, there may be cases where the height adjustment of the control gate electrode CGs is limited or the size of the sidewall memory gate electrode MGs has to be reduced beyond the range controlled by the height adjustment. In such cases, the first conductive film 3 is thinly formed in advance in the process described with reference to FIG. 6.

However, the further studies made by the present inventors have revealed that, when the first conductive film 3 is formed thinly, the following problems occur.

The first conductive film 3 becomes the sidewall memory gate electrode MGs in the subsequent processing, and at the same time, it is also a conductive film to be the single memory gate electrode MGu. Therefore, forming the first conductive film 3 thinly means that the film of the single memory gate electrode MGu is thinned. On the other hand, as described with reference to FIG. 1, the single memory gate electrode MGu is used as the ion implantation mask when the n type extension region ne2 is formed in the second region R2. Therefore, if the film of this single memory gate electrode MGu is thinned, the single memory gate electrode MGu cannot carry out the function as an ion implantation mask, so that a diffusion layer is formed outside the desired region.

The method for solving the above problems will be described below. FIG. 15 is a cross sectional view of a principal part showing the manufacturing process continued from FIG. 6. As compared with the process described in FIG. 6, the first conductive film 3 is thinly formed here. The thickness of the first conductive film 3 is determined depending on the size of the sidewall memory gate electrode MGs formed by anisotropic etching later. Further, a first protection film 6 is formed so as to cover the first conductive film 3. In this manner, a sufficient thickness as a later ion implantation mask is secured by additionally depositing the first protection film 6 on the first conductive film 3.

In the subsequent processes, the unnecessary first protection film 6 is removed by etching. At this time, in the second region R2, the first protection film 6 needs to be left in a region to be the single memory gate electrode MGu later. Therefore, a photoresist film 7 is formed as the etching mask by, for example, the photolithography and others so that the first protection film 6 of this region is not exposed to etching. Here, it is necessary to remove all the first protection films 6 in the regions other than the second region R2 so that this film does not remain in a step part and the like. Therefore, in this process, the first protection film 6 is removed by applying isotropic etching.

Furthermore, it is necessary to prevent the influence of the isotropic etching from reaching the first conductive film 3 exposed when the first protection film 6 is removed by the isotropic etching. This is because the sidewall memory gate electrode MGs needs to be formed by leaving the first conductive film 3 in self-alignment on the sidewall of the control gate electrode CGs in the first region R1 by the later anisotropic etching. Therefore, a material with a high selectivity for the underlying first conductive film 3 in the isotropic etching, that is, a material having largely different etching rate is used as the first protection film 6. In the first embodiment, the first conductive film 3 is polycrystalline silicon and the first protection film is, for example, a silicon oxide film.

Also, the first protection film 6 may be made of any material as long as it has a high selectivity for polycrystalline silicon and also may be a conductive film different from the polycrystalline silicon. It is more preferable that the first protection film 6 is a conductive film with electrical conductivity because this film is formed so as to cover the upper surface of the single memory gate electrode MGu later.

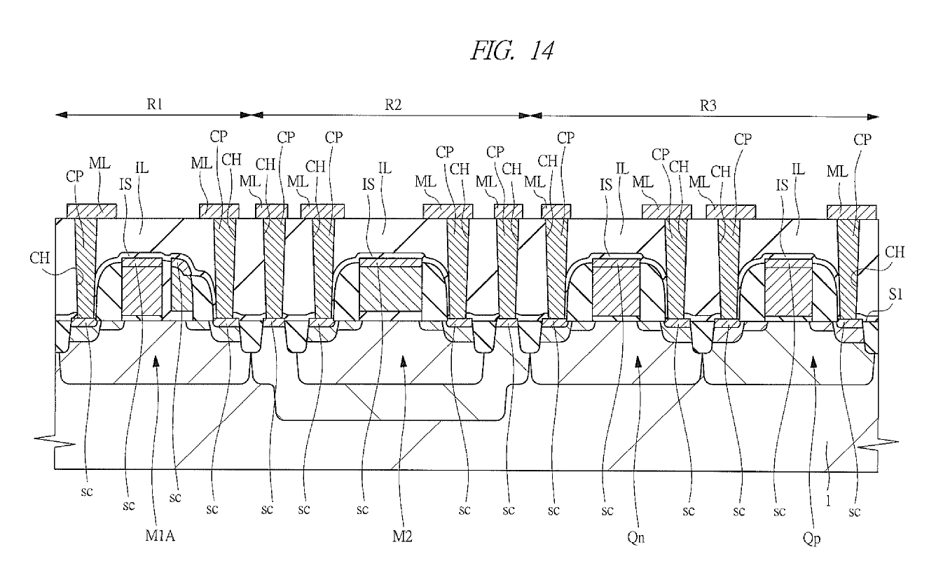

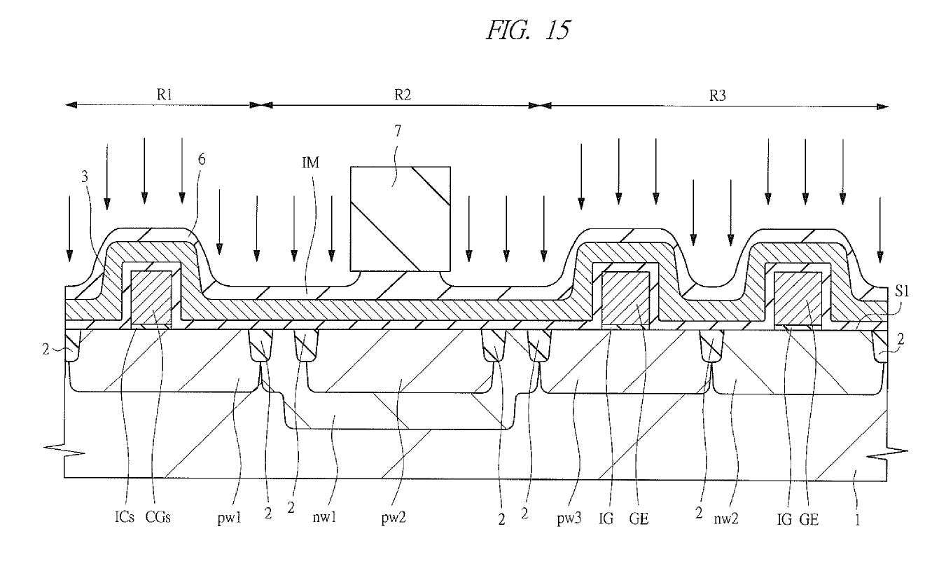

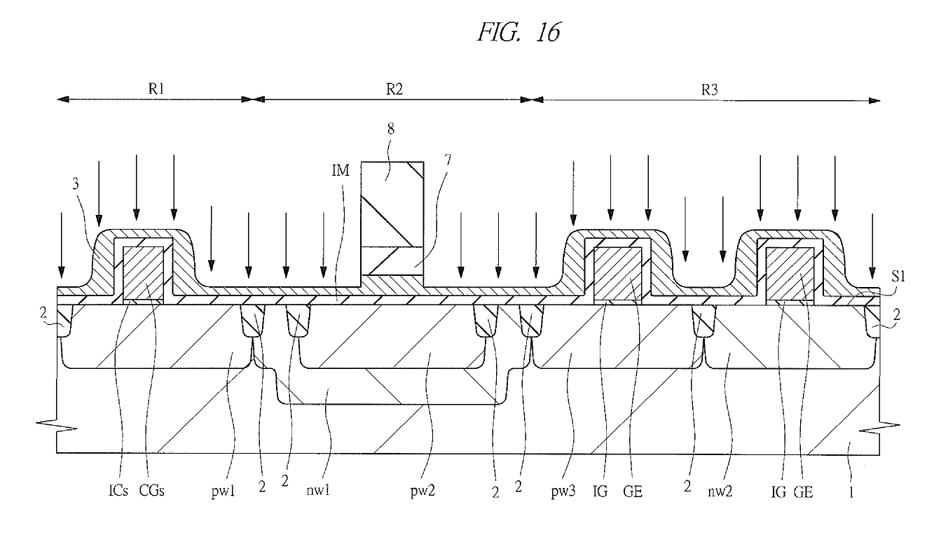

Thereafter, as shown in FIG. 16, in the second region R2, a photoresist film 8 is formed so as to cover the first conductive film 3 in the region that is desired to be left as the single memory gate electrode MGu and the first protection film 6 formed thereon. The photoresist film 8 is processed by the photolithography so as to have a width equivalent to the gate width of the single memory gate electrode MGu. Therefore, the width of the photoresist film 8 is narrower than that of the photoresist film 7 (FIG. 15) formed as the etching mask for the isotropic etching of the previous first protection film 6. Then, anisotropic etching is applied to the first conductive film 3 with using this photoresist film 8 as the etching mask in the same manner as described with reference to FIG. 7.

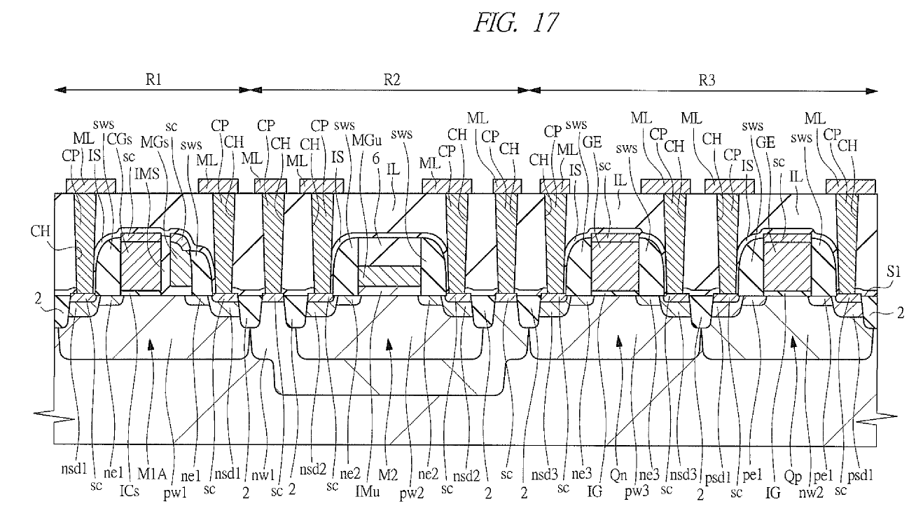

Thereafter, by performing the same processes as those described with reference to FIG. 9 to FIG. 14, a nonvolatile semiconductor storage device is formed as shown in FIG. 17. Here, the single memory gate electrode MGu of the single-gate memory cell M2 formed in the second region R2 has the first protection film 6 formed to cover the upper surface thereof. As described above, the first protection film 6 is additionally deposited onto the single gate electrode MGu in the course of the process. By this means, the single memory gate electrode MGu can have a film thickness capable of sufficiently functioning as the ion implantation mask used when the n type extension region ne2 is formed.

As described above, by additionally depositing the single memory gate electrode MGu by using the first protection film 6, the size of the sidewall memory gate electrode MGs can be reduced without affecting other processes. As a result, the performance of the nonvolatile semiconductor storage device can be further improved.

### Second Embodiment

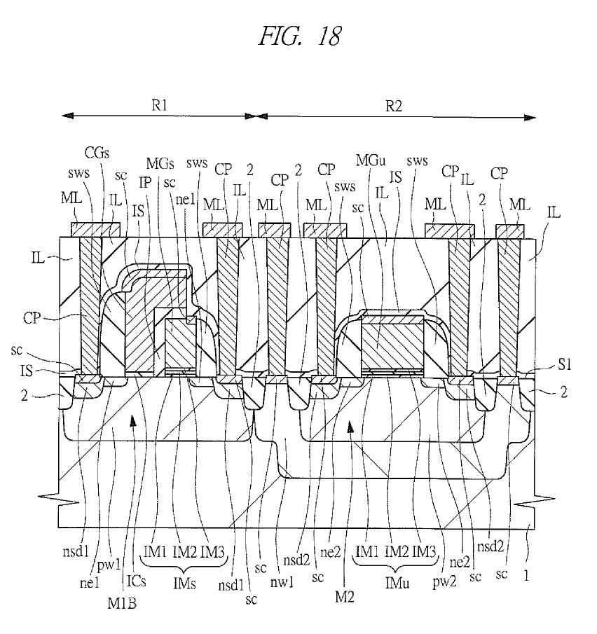

The second embodiment shows a technique for forming two types of memory cells with different structures on the same substrate by a method different from the manufacturing method shown in the first embodiment. Since it is manufactured by the different method, a nonvolatile semiconductor storage device having a structure different from the first embodiment is formed. First, the structure of the nonvolatile semiconductor storage device shown in the second embodiment will be described here with reference to FIG. 18.

The structure of the nonvolatile semiconductor storage device of the second embodiment shown in FIG. 18 has almost the same structure as that of the first embodiment except for the following points. Only different points will be described here, and other points are the same as those of the structure described with reference to FIG. 1.

In the nonvolatile semiconductor storage device of the second embodiment, the structure of a split-gate memory cell (first storage element) M1B formed in the first region R1 of the silicon substrate 1 differs from that of the first embodiment in the following points.

More specifically, a protection insulating film IP is formed between the control gate electrode CGs and the sidewall memory gate electrode MGs. The protection insulating film IP is an insulating film mainly made of silicon oxide formed for the purpose of the insulation between the adjacently disposed control gate electrode CGs and sidewall memory gate MGs. Therefore, for the proper insulation between both the electrodes, the protection insulating film IP is thick as compared with the control gate insulating film IGs. Also, the control gate electrode CGs may be shaped to have a part extending over a part of the upper surface of the sidewall memory gate electrode MGs. Even in this case, the protection insulating film IP is formed between the control gate electrode CGs and the sidewall memory gate electrode MGs to insulate both the electrodes.

Also the split-gate memory cell M1B with such a shape operates based on almost the same operation principle as the split-gate memory cell M1A of the first embodiment. More specifically, the memory operation excellent in high-speed performance is possible. Also, in the second embodiment, a nonvolatile memory in which the split-gate memory cell M1B with high-speed performance and the single-gate memory cell M2 with high write and erase endurance are embedded on the same silicon substrate 1 can be realized. As a result, the performance of the nonvolatile semiconductor storage device can be improved.

In the following, the manufacturing method of the nonvolatile semiconductor storage device with the above-described structure shown in the second embodiment will be described. Also in this case, the parts different from those in the manufacturing process of the first embodiment will be mainly described in detail. More specifically, the processes and material characteristics and others whose detailed descriptions are omitted in the second embodiment are the same as those in the first embodiment.

The initial processes are the same as those of the method described with reference to FIG. 2 to FIG. 4. In the first embodiment, the control gate insulating film IGs and the control gate electrode CGs are formed in the first region R1 immediately after the process in FIG. 4.

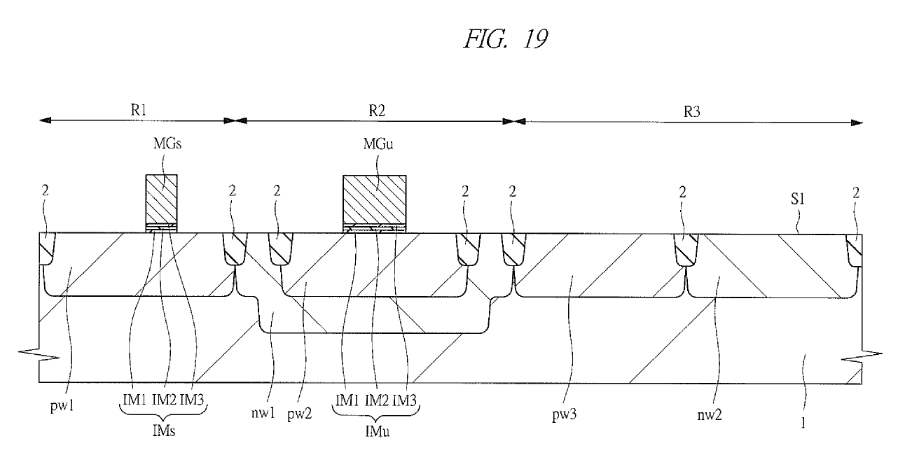

Meanwhile, in the second embodiment, as shown in FIG. 19, the sidewall memory gate electrode MGs is formed in the first region R1 via the charge trapping film IMs. Then, the single memory gate electrode MGu is formed in the second region R2 via the charge trapping film IMu. In particular, the sidewall memory gate electrode MGs and the single memory gate electrode MGu are formed in the first region R1 and the second region R2 in the same process, and also, the charge trapping film IMs and the charge trapping film IMu are formed in the same process.

More specifically, after the process shown in FIG. 4 ends, the first insulating film IM1, the second insulating film IM2, and the third insulating film IM3 are formed in this order on the main surface S1 of the silicon substrate 1. The type, requested function, and forming method of each insulating film are the same as those in the first embodiment. Then, a polycrystalline silicon film is formed by, for example, the CVD method and others so as to cover the main surface S1 of the silicon substrate 1.

Subsequently, anisotropic etching is applied to the polycrystalline silicon film with using a photoresist film (not shown) formed by, for example, the photolithography and others as the etching mask. By this means, the sidewall memory gate electrode MGs is formed in the first region R1 and the single memory gate electrode MGu is formed in the second region R2.

Subsequently, anisotropic etching is applied to the first to third insulating films IM1 to IM3 with using the above photoresist film as the etching mask. By this means, the charge trapping film IMs is formed under the sidewall memory gate electrode MGs of the first region R1, and the charge trapping film IMu is formed under the single memory gate electrode MGu of the second region R2. In this manner, the structure shown in FIG. 19 is obtained.

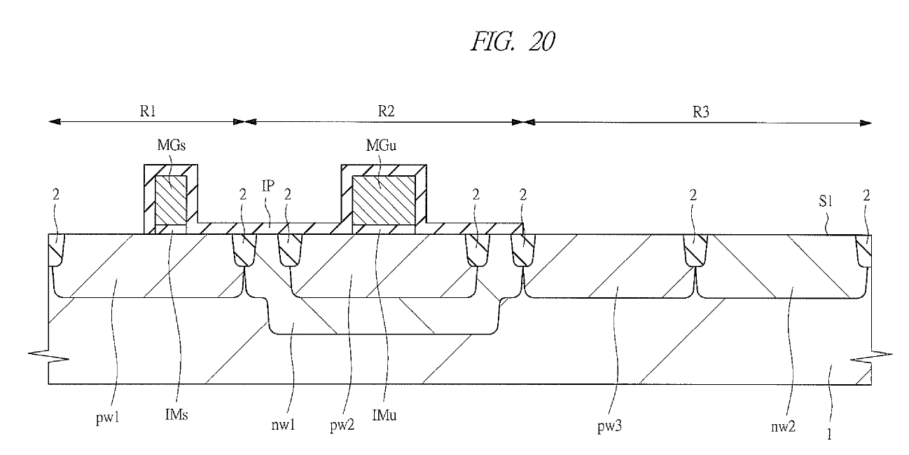

Next, as shown in FIG. 20, the protection insulating film IP is formed on the main surface S1 of the silicon substrate 1 so as to cover the sidewall memory gate electrode MGs of the first region R1 and the single memory gate electrode MGu of the second region R2. The procedure thereof will be shown below.

First, the protection insulating film IP that is an insulating film mainly made of silicon oxide is formed on the main surface S1 of the silicon substrate 1 by, for example, the thermal oxidation method and others. Subsequently, unnecessary part of the protection insulating film IP is removed by etching. At this time, an etching mask made of, for example, a photoresist film is formed in advance in the region where the protection insulating film IP is not removed to be left so that it is not exposed to the etching. In the second embodiment, the region where the protection insulating film IP is left and the region where it is removed are as shown below.

As described with reference to FIG. 18, the protection insulating film IP is formed for the purpose of insulation between the control gate electrode CGs and the sidewall memory gate electrode MGs formed later in the first region R1. Therefore, it is necessary to leave the protection insulating film IP in a part that covers the sidewall memory gate electrode MGs of the first region R1.

On the other hand, as described with reference to FIG. 18, the control gate electrode CGs is disposed on one side of the sidewall memory gate electrode MGs. Here, it is necessary to form the control gate insulating film ICs between the control gate electrode CGs and the silicon substrate 1. Note that this control gate insulating film ICs cannot be replaced with a simply thick protection insulating film IP because it relates to the performance of the split-gate memory cell M1B as a MIS transistor. Therefore, it is necessary to remove the protection insulating film IP on the main surface S1 of the silicon substrate 1 where the control gate electrode CGs is to be formed later, on the side of the sidewall memory gate electrode MGs.

For the same reason, it is also necessary to remove the protection insulating film IP of the third region R3 where a peripheral circuit is to be formed. More specifically, in the third region R3, a MIS transistor having a gate insulating film whose thickness is determined by the characteristics is formed, and the protection insulating film IP is unnecessary.

Also, in the second embodiment, the protection insulating film IP is left also in the second region R2 so that the single memory gate electrode MGu is not exposed to the later anisotropic etching process.

In the region described above where the protection insulating film IP is to be left, a photoresist film (not shown) is formed by, for example, the photolithography and others. Then, the unnecessary protection insulating film IP is removed by applying etching to the protection insulating film IP with using the photoresist film as the etching mask.

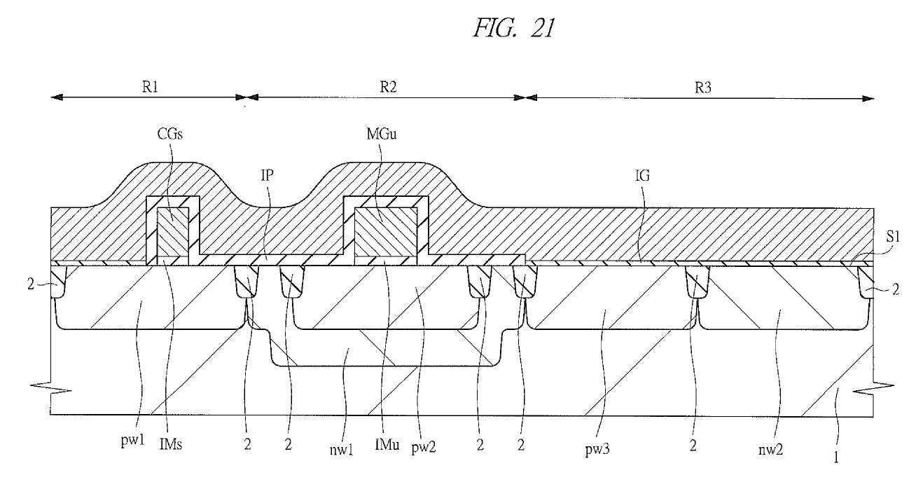

Next, as shown in FIG. 21, of the regions where the above-described protection insulating film IP is not formed on the main surface of the silicon substrate 1, the control gate insulating film ICs is formed in the first region R1 and the gate insulating film IG is formed in the third region R3.

Here, in the second embodiment, the control gate insulating film ICs of the first region R1 and the gate insulating film IG of the third region R3 are formed in the same process. For example, the main surface S1 of the silicon substrate 1 is oxidized by, for example, the thermal oxidation method and others to form an insulating film mainly made of silicon oxide, thereby forming both of these insulating films.

Thereafter, a second conductive film 9 is formed so as to cover the main surface S1 of the silicon substrate 1. The second conductive film 9 is a conductive film mainly made of polycrystalline silicon and is formed by, for example, the CVD method and others.

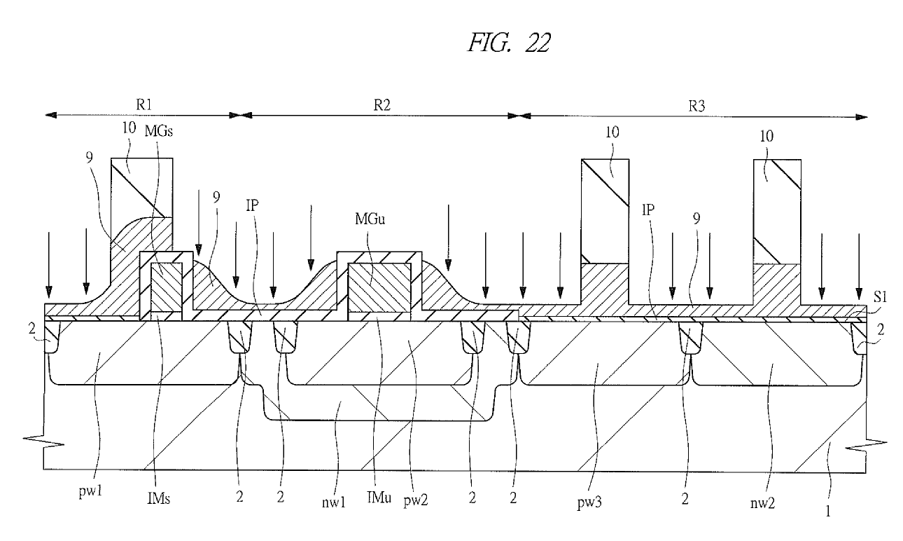

In the next process, as shown in FIG. 22, the control gate electrode CGs (see FIG. 18) and the gate electrode GE (for example, see FIG. 5) are collectively formed in the first region R1 and the third region R3, respectively, by processing the second conductive film 9. Here, the second conductive film 9 other than the parts to be left as the respective electrodes is removed by anisotropic etching. A photoresist film 10 is formed as the etching mask for the anisotropic etching by, for example, the photolithography and others. The second conductive film 9 not covered with the photoresist film 10 is removed by applying anisotropic etching. Then, the unnecessary protection insulating film IP, control gate insulating films ICs, and gate insulating films IG are removed by the similar etching.

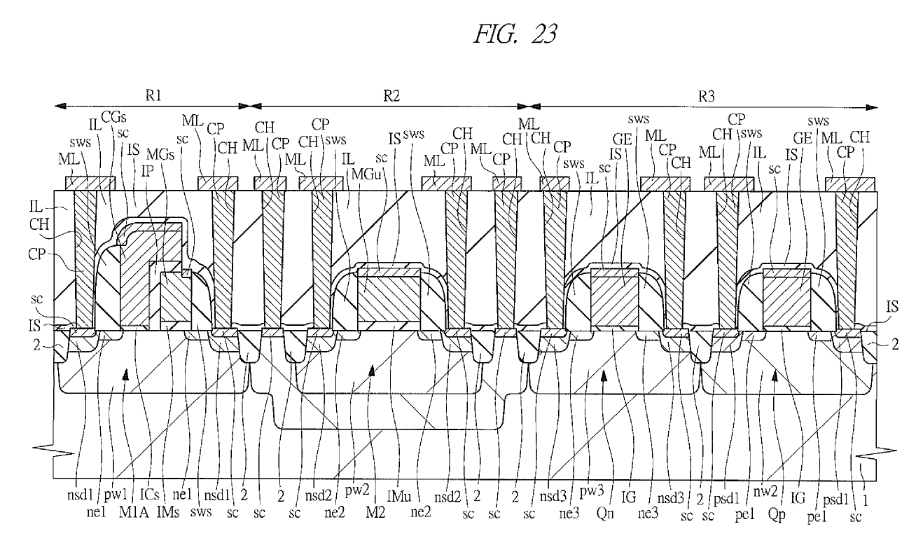

Through the processes described above, as shown in FIG. 23, on the main surface S1 of the silicon substrate 1, the control gate electrode CGs is formed in the first region R1 via the control gate insulating film ICs and the gate electrode GE is formed in the third region R3 via the gate insulating film IG. In particular, the specifications of the control gate insulating film ICs and control gate electrode CGs of the first region R1 are the same as those described with reference to FIG. 18.

In the subsequent processes, the same processes as those described with reference to FIG. 11 to FIG. 14 in the first embodiment are performed, thereby forming the nonvolatile semiconductor storage device of the second embodiment having the structure shown in FIG. 23.

Through the processes described above, on the same silicon substrate 1, the split-gate memory cell M1B shown in FIG. 18 can be formed in the first region R1 and the single-gate memory cell M2 shown in the same figure can be formed in the second region R2. Therefore, it is possible to form a memory cell with high-speed performance and a memory cell with high write and erase endurance on the same substrate although the structures differ from those of the first embodiment. In addition, according to the technique of the second embodiment, most of the elements constituting the two types of memory cells can share their forming processes. In other words, the two types of memory cells can be embedded without remarkable increase in manufacturing processes. As a result, the performance of the nonvolatile semiconductor storage device can be improved.

Also, in the first embodiment described above, both the memory gate electrodes MGs and MGu are formed after the control gate electrode CGs of the split-gate memory cell M1A is formed. Meanwhile, in the second embodiment, the control gate electrode CGs is formed after both the memory gate electrodes MGs and MGu are formed. According to the studies made by the present inventors, the quality of the charge trapping film IM which retains information significantly affects the memory characteristics of the nonvolatile semiconductor storage device. Therefore, in this viewpoint, a manufacturing method for forming both the memory gate electrodes MGs and MGu having the charge trapping film IM at the earliest possible stage is more preferable.

Also, in the second embodiment, it is necessary to form the protection insulating film IP in a process separate from a process for forming the control gate insulating film ICs and the first insulating film IMP, and the process for processing the protection insulating film IP is required. Meanwhile, in the technique of the first embodiment that does not include this process, the number of processes can be further reduced. Further, the fact that the number of manufacturing processes can be reduced means productivity improvement such as yield improvement and manufacturing cost reduction. Therefore, in this viewpoint, a manufacturing method that can reduce the number of processes is more preferable.

### Third Embodiment

A third embodiment shows a technique for disposing each memory cell suited to the actual use in a nonvolatile semiconductor storage device in which a split-gate memory cell with high-speed performance and a single-gate memory cell with high write and erase endurance are provided on the same chip.

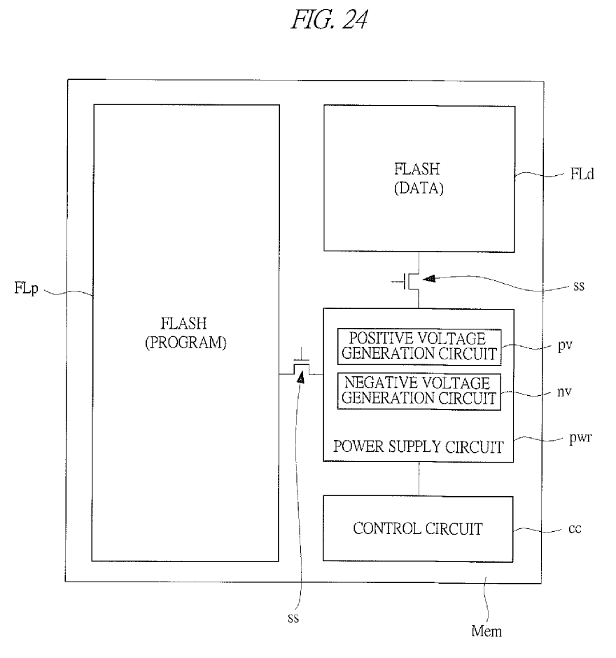

FIG. 24 is an explanatory drawing showing a memory block Mem extracted from the elements that constitute the nonvolatile semiconductor storage device of the third embodiment. In the nonvolatile semiconductor storage device of the third embodiment, all of their configurations are formed on the same silicon substrate 1 like in the first and second embodiments.

The memory block Mem includes a program memory region FLp (first memory region) that is a region where a nonvolatile memory (or FLASH) for storing program information (first information) of a logic circuit is disposed. Also, the memory block Mem includes a data memory region FLd (second memory region) that is a region where a nonvolatile memory for storing data information (second information) necessary for operation is disposed.

The program information is used to make a logic circuit perform arithmetic operation for processing operation, and is usually written only once in the product shipment. Therefore, program information is rarely rewritten, but needs to be read at high speed because it relates to processing operation of an integrated circuit. On the other hand, as the data information, operating states and error information are stored and retained as data. Therefore, as compared with the program information, the data information does not require high-speed performance, but requires endurance for frequent rewriting. Therefore, in the third embodiment, the program memory region FLp and the data memory region FLd that require different characteristics as described above are separately configured.

Also, the first region R1 where the split-gate memory cells Kax, M1A, and M1B (hereinafter simply referred to as a split-gate memory cell Ms) are disposed in the first and second embodiments is allocated as the program memory region FLp. Furthermore, in the third embodiment, the second region R2 where the single-gate memory cells Kcx and M2 (hereinafter simply referred to as a single-gate memory cell Mu) are disposed in the first and second embodiments is allocated as the data memory region FLd. By this means, the split-gate memory cell Ml excellent in high-speed read operation and the single-gate memory cell M2 excellent in write and erase endurance can be utilized for appropriate applications.

Note that the nonvolatile semiconductor storage device studied by the present inventors requires storage capacity of several megabytes (MB) for the program memory region FLp and storage capacity of hundreds of kilobytes (KB) for the data memory region FLd. Therefore, in the memory block Mem, the program memory region FLp occupies a wider area than the data memory region FLd.

As described in the first embodiment with reference to FIG. 30 to FIG. 35, in the operation of a nonvolatile memory, higher voltage supply is required as compared with the operation of a normal element. The high voltage may be supplied from an external power supply, but in the nonvolatile semiconductor storage device of the third embodiment, the memory block Mem is provided with a power supply circuit pwr and voltage is supplied from the inside.

Here, in the nonvolatile semiconductor storage device of the third embodiment, the program memory region FLp and the data memory region FLd do not have individual power supplies, but share the same power supply circuit pwr. More specifically, the split-gate memory cell Ms disposed in the program memory region FLp and the single-gate memory cell Mu disposed in the data memory region FLd are electrically connected to the power supply circuit pwr, and this power supply pwr circuit supplies voltage to the split-gate memory cell Ms and the single-gate memory cell Mu. Accordingly, it is possible to reduce the chip area in the nonvolatile semiconductor storage device having two types of memory cells provided on the same chip and including an internal power supply.

Meantime, as described in the first embodiment, the operation principle of the split-gate memory cell Ms differs from that of the single-gate memory cell Mu, and therefore, the voltage supply specifications thereof also differ. For example, in the split-gate memory cell Ms, approximately 10 V is applied as the memory gate voltage Vgm in write operation and approximately −5 V is applied as the memory gate voltage Vgm in erase operation as described with reference to FIG. 30 and FIG. 31. On the other hand, in the single-gate memory cell Mu, approximately 14 V is applied as the memory gate voltage Vgm in write operation and approximately −14 V is applied as the memory gate voltage Vgm in erase operation as described with reference to FIG. 34 and FIG. 35.

For the achievement of the voltage application conditions above, the power supply circuit pwr of the third embodiment includes a positive voltage generation circuit pv and a negative voltage generation circuit nv. In addition, a selector switch ss is disposed on the electrical connection between the split-gate memory cell Ms disposed in the program memory region FLp and the power supply circuit pwr. Similarly, a selector switch ss is disposed on the electrical connection between the single-gate memory cell Mu disposed in the data memory region FLd and the power supply circuit pwr. These selector switches ss are provided to distribute the positive or negative voltage supplied from the power supply circuit pwr to the program memory region FLp or the data memory region FLd.

Also, the voltage distribution and switching timing are controlled by a control circuit cc. The control circuit cc is provided in the memory block Mem so as to be electrically connected to the selector switch ss. The selector switch ss is, for example, a field-effect transistor and others.

Here, the single-gate memory cell Mu disposed in the data memory region FLd requires positive and negative voltages of approximately 14 V as the memory gate voltage Vgm in its operations. This voltage is high as compared with other elements. In the elements that require such high voltage, physical damages on the components thereof, an operation failure due to the influence of electric field to other elements (so-called disturb phenomenon) and others are likely to occur. They cause the decrease of the reliability of the nonvolatile semiconductor storage device. Therefore, in the third embodiment, the application method of the memory gate voltage Vgm in the operation of the single-gate memory cell Mu is defined as follows.

That is, not only the voltage is applied to the single memory gate electrode MGu described with reference to FIG. 1 but also reverse-polarity voltage is applied to the second p well pw2. For example, 7 V is applied to the single memory gate electrode MGu and −7 V is applied to the second p well pw2. By this means, voltage absolutely lower than 14 V is applied to each element, and at the same time, relatively 14 V bias can be applied as the memory gate voltage Vgm. As a result, the reliability of the nonvolatile semiconductor storage device can be improved.

Furthermore, as described with reference to FIG. 1 in the first embodiment, the single-gate memory cell Mu disposed in the data memory region FLd in the third embodiment is electrically isolated from the silicon substrate 1 by the triple well structure using the first n well nw1. Therefore, even if it is necessary to apply the voltage specific to the second p well pw2 where the single-gate memory cell Mu is formed as described above, it is unlikely that the influence of the electric field reaches the other elements formed on the same silicon substrate 1. Accordingly, stable operation and data storage of each memory element become possible. As a result, the performance of the nonvolatile semiconductor storage device can be further improved.

Next, a method for arranging the respective memory cells Ms and Mu in the memory regions FLp and FLd in the memory block Mem of the third embodiment will be shown.

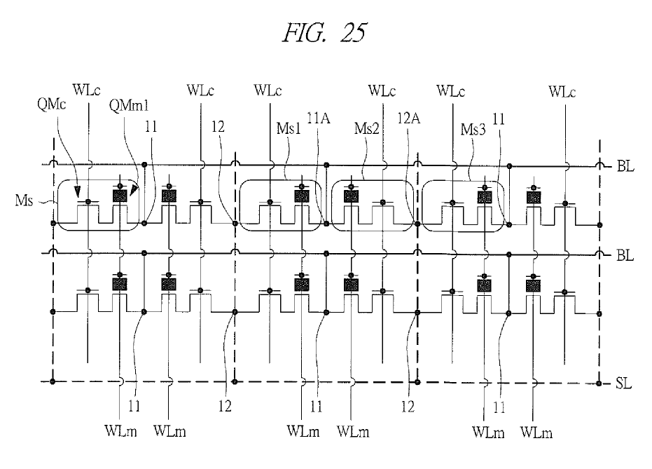

FIG. 25 is a circuit diagram showing the arrangement (array configuration) of the split-gate memory cell Ms in the program memory region FLp. For example, as described with reference to FIG. 1 in the first embodiment, the split-gate memory cell Ms includes the control gate electrode CGs and the sidewall memory gate electrode MGs adjacently disposed to each other in a state of being isolated from each other. Also, the respectively independent control gate voltage Vgc or memory gate voltage Vgm is applied thereto in memory operation. Therefore, one split-gate memory cell Ms is described in the circuit diagram so as to be configured of a control gate transistor QMc that operates with the control gate electrode CGs and a memory gate transistor QMm1 that operates with the sidewall memory gate electrode MGs.

In the program memory region FLp of the third embodiment, a plurality of split-gate memory cells Ms are arranged in a not OR (NOR) type. In general, in the NOR-type memory cell arrangement, write and read in units of cell can be carried out by a method using three wires such as a word line, a data line, and a source line. It also has a characteristic of high-speed random access. For these reasons, the NOR-type memory cell arrangement is suited to the memory arrangement for program storage. Therefore, also in the third embodiment, by arranging the split-gate memory cells Ms capable of high-speed operation in the NOR type in the program memory region FLp, the performance of the nonvolatile semiconductor storage device can be further improved. A concrete connection method will be described below.

Power is supplied via a control word line WLc to the gate (corresponding to the control gate electrode CGs in FIG. 1) of the control gate transistor QMc constituting the split-gate memory cell Ms. Also, power is supplied via a memory word line WLm to the gate (corresponding to the sidewall memory gate electrode MGs in FIG. 1) of the memory gate transistor QMm1.

Also, the same bit contact 11 is shared by two adjacent split-gate memory cells Ms for a bit line BL. For example, cells Ms1 and Ms2 that are adjacent to each other share the bit contact 11A for the bit line BL. Similarly, the same source contact 12 is shared by two adjacent split-gate memory cells Ms for a source line SL. For example, two cells Ms2 and Ms3 that are adjacent to each other share the source contact 12A for the source line SL.

In the actual split-gate memory cell Ms, of the contact plugs CP shown in FIG. 1, the contacts 11 and 12 shared as described above correspond to those which supply power to the n type source/drain regions nsd1 formed in the first p well pw1.

As described above, in the program memory region FLp of the third embodiment, the speed-up is achieved by arranging the split-gate memory cells Ms in the NOR type, and further, the space-saving is achieved by sharing some of the contacts 11 and 12 by a plurality of cells. As a result, the performance of the nonvolatile semiconductor storage device can be further improved.

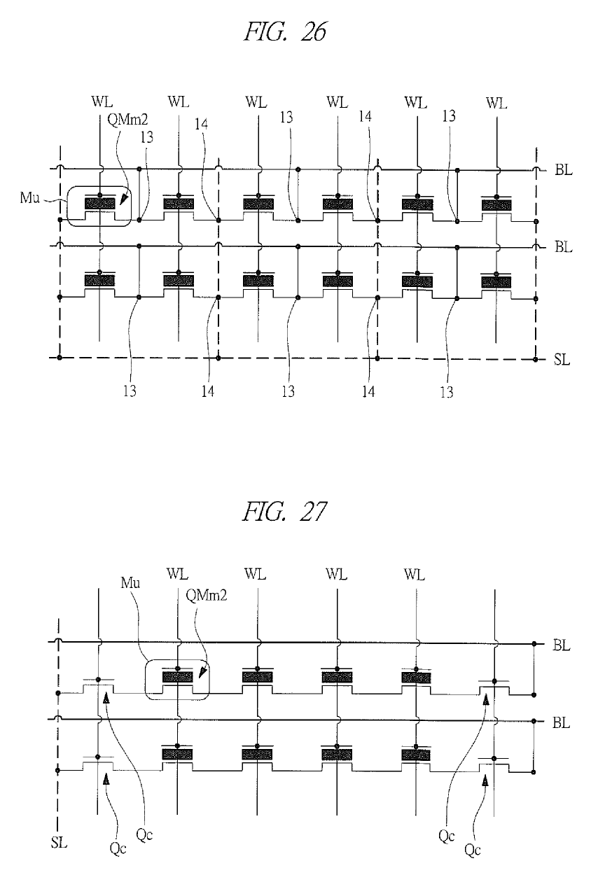

The above NOR-type arrangement is also applicable to a method for arranging the single-gate memory cells Mu in the data memory region FLd. FIG. 26 shows a circuit diagram when the single-gate memory cells Mu are arranged in the NOR type in the data memory region FLd. As describe with reference to FIG. 1 in the first embodiment, the single-gate memory cell Mu is a transistor having a single memory gate electrode. Therefore, one single-gate memory cell Mu is described in the circuit diagram so as to be configured of one memory gate transistor QMm2.

The connection method of the single-gate memory cell Mu in the NOR type arrangement in the data memory region FLd of the third embodiment is almost the same as the connection method described above with reference to FIG. 25.

More specifically, power is supplied to the gate (corresponding to the single memory gate electrode MGu shown in FIG. 1) of the memory gate transistor QMm2 via the word line WL. Also, the same bit contact 13 is shared by two adjacent single-gate memory cells Mu for the bit line BL. Similarly, the same source contact 14 is shared by two adjacent single-gate memory cells Mu for the source line SL. In the actual single-gate memory cell Mu, of the contact plugs CP shown in FIG. 1, the contacts 13 and 14 shared as described above correspond to those which supply power to the n type source/drain regions nsd2 formed in the second p well pw2.

As described above, in the data memory region FLd of the third embodiment, the single-gate memory cells Mu are arranged in the NOR type and some of the contacts 13 and 14 are shared by a plurality of cells, thereby achieving the space-saving. As described above, by arranging the memory cells in NOR type not only in the program memory region FLp but also in the data memory region FLd, the performance of the nonvolatile semiconductor storage device can be further improved.

Note that, since the single-gate memory cell Mu is composed of a single memory gate transistor QMm2 as described above, if it is always in a conductive state, it becomes unable to function as a memory. Therefore, in a situation where the predetermined voltage is not applied to the word line WL in the read operation, a threshold voltage needs to be controlled so as to prevent the cell from being always in a conductive state.

Also, the arrangement of the single-gate-memory cells Mu in the data memory region FLd may be the not AND (NAND) type. FIG. 27 is a circuit diagram showing the case where the single-gate memory cells Mu are arranged into the NAND type in the data memory region FLd.

Similar to the NOR type shown in FIG. 26, power is supplied via the word line WL to the gate of the memory gate transistor QMm2 constituting the single-gate memory cell Mu. Also, the contacts to be connected to the bit line BL and the source line SL do not exist between adjacent single-gate memory cells Mu. In other words, the adjacent single-gate memory cells Mu are electrically connected in series. For this reason, as compared with the NOR type shown in FIG. 26, the single-gate memory cells Mu can be arranged more densely.

At this time, write, erase, and read operations are collectively performed to a plurality of single-gate memory cells Mu connected to the same bit line BL as memory operation. This operation principle does not cause any problem in the data memory region FLd used for frequent rewriting of a large capacity data. Also, there is no problem in memory operation even when the single-gate memory cells Mu are in a conductive state in a situation where voltage is not applied to the word line WL. This is because both ends of the plurality of the single-gate memory cells Mu connected in series are connected to the bit line BL and the word line WL via the control MIS transistor Qc. Therefore, the NAND-type arrangement in which memory cells can be arranged more densely without causing any operational problem is more preferable as the method for arranging the single-gate memory cells Mu in the data memory region FLd.

As described above, according to first to third embodiments, by embedding two types of memory cells whose structures and operation principles differ on the same substrate, a nonvolatile memory capable of individually responding to the requests for high-speed performance and high write and erase endurance can be configured. Further, reduction in productivity such as decrease in yield and increase in manufacturing cost does not occur because introduction of new manufacturing processes and large increase in the number of existing manufacturing processes are not required for the above-described embedding. Also, areas of a power supply circuit and a cell array do not increase and chip miniaturization is not prevented even in the integration on the same chip. In this manner, the performance of the nonvolatile semiconductor storage device can be improved.

In the foregoing, the invention made by the present inventors has been concretely described based on the embodiments. However, it is needless to say that the present invention is not limited to the foregoing embodiments and various modifications and alterations can be made within the scope of the present invention.

For example, in the first to third embodiments, structures in which split-gate memory cells and single-gate memory cells are formed as n channel MIS transistors in a p well have been shown. The polarities and positional relationships of these can be reversed. In this case, a desired structure can be formed by reversing the mentioned polarities.

Also, for example, in the nonvolatile semiconductor storage devices illustrated in the first to third embodiments, a separating portion of STI structure has been shown as the separating portion that defines the regions where a plurality of elements are formed on the same substrate. Here, the separating portion can have the so-called LOCOS (Local Oxidation of Silicon) structure.

The present invention can be applied to, for example, semiconductor industries necessary for information processing in personal computers, mobile devices and others.

What is claimed is:

1. A manufacturing method of a nonvolatile semiconductor storage device comprising the steps of:
(a) preparing a semiconductor substrate of a first conductivity type having a first region and a second region on its main surface;
(b) forming a first gate electrode on the main surface of the semiconductor substrate in the first region via a first gate insulating film;
(c) forming a charge trapping insulating film and a first conductive film in order so as to cover the main surface of the semiconductor substrate in the first region and the second region; and
(d) after the step (c), processing the first conductive film, thereby forming a second gate electrode in the first region and a third gate electrode in the second region,
wherein the step (c) and the step (d) are performed before or after the step (b),
in the first region, the first gate electrode and the second gate electrode are formed so as to be adjacently disposed to each other in a state of being electrically isolated from each other,
the first gate electrode and the second gate electrode are a part of elements which constitute a first storage element in the first region, and
the third gate electrode is a part of elements which constitute a second storage element in the second region.

2. The manufacturing method of a nonvolatile semiconductor storage device according to claim 1 further comprising the steps of: before the step (c),
(e) forming a first semiconductor region of a second conductivity type opposite to the first conductivity type in the second region; and
(f) forming a second semiconductor region of the first conductivity type in the first semiconductor region,
wherein, in the step (d), the first conductive film is processed so that the third gate electrode is planarly disposed in the second semiconductor region, and
the second storage element is planarly disposed in the second semiconductor region.

3. The manufacturing method of a nonvolatile semiconductor storage device according to claim 2,
wherein a first insulating film, a second insulating film, and a third insulating film are formed in order as the charge trapping insulating film,
the second insulating film is an insulating film for storing electric charge, and
the first insulating film and the third insulating film which sandwich the second insulating film are insulating films for preventing leakage of electric charge stored in the second insulating film to outside.

4. The manufacturing method of a nonvolatile semiconductor storage device according to claim 3,
wherein the first insulating film is an insulating film mainly made of silicon oxide with a thickness of 4 to 6 nm,
the second insulating film is an insulating film mainly made of silicon nitride with a thickness of 5 to 10 nm or an insulating film mainly made of metal oxide with a thickness of 8 to 12 nm,
the third insulating film is an insulating film mainly made of the silicon oxide with a thickness of 5 to 9 nm or an insulating film mainly made of aluminum oxide with a thickness of 5 to 9 nm, and
the metal oxide has a higher relative dielectric constant than the silicon oxide.

5. The manufacturing method of a nonvolatile semiconductor storage device according to claim 4,
wherein the meal oxide is hafnium oxide.

6. The manufacturing method of a nonvolatile semiconductor storage device according to claim 1,
wherein, by performing the steps (c) and (d) after the step (b), the charge trapping insulating film formed between the semiconductor substrate and the second gate electrode is formed also between the first gate electrode and the second gate electrode in an integrated manner, and
the first gate electrode and the second gate electrode are formed so as to be adjacently disposed to each other in a state of being electrically isolated from each other by the charge trapping insulating film.

7. The manufacturing method of a nonvolatile semiconductor storage device according to claim 6 further comprising the steps of: after the step (c) and before the step (d),
(g) forming a first protection film so as to cover the first conductive films in the first region and the second region; and
(h) removing the first protection film in the first region by isotropic etching,
wherein, in the step (d), in addition to the processing of the first conductive film, the first protection film is processed so as to remain on the third gate electrode, and
a rate of the isotropic etching for the first protection film differs from that for the first conductive film.

8. The manufacturing method of a nonvolatile semiconductor storage device according to claim 1,
wherein the step (c) and the step (d) are performed before the step (b),
the method further comprises the step of:
(i) after the step (d), forming a protection insulating film so as to cover the second gate electrode,
by forming the first gate electrode in the step (b) after the step (i), the protection insulating film is formed between the first gate electrode and the second gate electrode, and
the first gate electrode and the second gate electrode are formed so as to be adjacently disposed to each other in a state of being electrically isolated from each other by the protection insulating film.

9. A nonvolatile semiconductor storage device comprising:
(a) a semiconductor substrate of a first conductivity type having a first region and a second region on its main surface;
(b) a first storage element disposed in the first region; and
(c) a second storage element disposed in the second region;
wherein the first storage element includes:
(b1) a first gate electrode formed on the main surface of the semiconductor substrate via a first gate insulating film; and
(b2) a second gate electrode formed on the main surface of the semiconductor substrate via a charge trapping insulating film,
the first gate electrode and the second gate electrode are adjacently disposed to each other in a state of being electrically isolated from each other, and
the second storage element includes:
(c1) a third gate electrode formed on the main surface of the semiconductor substrate via the charge trapping insulating film.

10. The nonvolatile semiconductor storage device according to claim 9 further comprising:
(d) a power supply circuit disposed on the main surface of the semiconductor substrate,
wherein the first storage element and the second storage element are electrically connected to the power supply circuit, and
voltage is supplied to the first storage element and the second storage element by the one power supply circuit.

11. The nonvolatile semiconductor storage device according to claim 10 further comprising:
(e) selector switches respectively disposed on an electrical connection between the first storage element and the power supply circuit and on an electrical connection between the second storage element and the power supply circuit,
wherein the power supply circuit further includes:
(d1) a positive voltage generation circuit which supplies positive voltage; and
(d2) a negative voltage generation circuit which supplies negative voltage, and
the selector switches have a function to switch the positive or negative voltage supplied from the power supply circuit to the first storage element or the second storage element.

12. The nonvolatile semiconductor storage device according to claim 11,
wherein the first region is allocated as a first memory region for storing first information,
the second region is allocated as a second memory region for storing second information,
the first information is information to be read at a higher speed than the second information, and
the second information is information to be rewritten more frequently than the first information.

13. The nonvolatile semiconductor storage device according to claim 12,
wherein a plurality of the first storage elements are arranged in a NOR type in the first region, and
a plurality of the second storage elements are arranged in the NOR type or a NAND type in the second region.

14. The nonvolatile semiconductor storage device according to claim 9 further comprising:
(f) a first semiconductor region of a second conductivity type opposite to the first conductivity type formed in the second region; and
(g) a second semiconductor region of the first conductivity type formed in the first semiconductor region,
wherein the second storage element is planarly disposed in the second semiconductor region.

15. The nonvolatile semiconductor storage device according to claim 14,
wherein the charge trapping insulating film includes a first insulating film, a second insulating film, and a third insulating film,
the second insulating film is disposed so as to be sandwiched between the first insulating film and the third insulating film,
the first insulating film, the second insulating film, and the third insulating film are deposited in this order from a side close to the semiconductor substrate,
the second insulating film is an insulating film for storing electric charge, and
the first insulating film and the third insulating film that sandwich the second insulating film are insulating films for preventing leakage of electric charge stored in the second insulating film to outside.

16. The nonvolatile semiconductor storage device according to claim 15,
wherein the first insulating film is an insulating film mainly made of silicon oxide with a thickness of 4 to 6 nm,
the second insulating film is an insulating film mainly made of silicon nitride with a thickness of 5 to 10 nm or an insulating film mainly made of metal oxide with a thickness of 8 to 12 nm, the third insulating film is an insulating film mainly
made of the silicon oxide with a thickness of 5 to 9 nm or an insulating film mainly made of aluminum oxide with a thickness of 5 to 9 nm, and
the metal oxide has a higher relative dielectric constant than the silicon oxide.

17. The nonvolatile semiconductor storage device according to claim 16,
wherein the metal oxide is hafnium oxide.

18. The nonvolatile semiconductor storage device according to claim 9,
wherein the charge trapping insulating film formed between the semiconductor substrate and the second gate electrode is formed also between the first gate electrode and the second gate electrode in an integrated manner, and
the first gate electrode and the second gate electrode are adjacently disposed to each other in a state of being electrically isolated from each other by the charge trapping insulating film.

19. The nonvolatile semiconductor storage device according to claim 18,
wherein the second storage element further includes:
(c2) a first protection film formed on the third gate electrode, and
a rate of isotropic etching for the first protection film differs from that for a first conductive film of the third gate electrode.

20. The nonvolatile semiconductor storage device according to claim 9,
wherein a protection insulating film is formed between the first gate electrode and the second gate electrode, and
the first gate electrode and the second gate electrode are adjacently disposed to each other in a state of being electrically isolated from each other by the protection insulating film.
